(19) United States
(12) Patent Application Publication
(10) Pub. No.: US 2026/0136859 A1
(43) Pub. Date: May 14, 2026

(54) ETCHING METHOD AND ETCHING DEVICE

(71) Applicant: Tokyo Electron Limited, Tokyo (JP)

(72) Inventors: Maju TOMURA, Miyagi (JP); Atsushi TAKAHASHI, Miyagi (JP); Noboru SAITO, Miyagi (JP); Noriyoshi ARIMA, Miyagi (JP); Ren MOMMA, Miyagi (JP); Shinya ISHIKAWA, Miyagi (JP); Takahiro YOKOYAMA, Miyagi (JP)

(73) Assignee: Tokyo Electron Limited, Tokyo (JP)

(21) Appl. No.: 19/440,695

(22) Filed: Jan. 6, 2026

Related U.S. Application Data
(63) Continuation of application No. PCT/JP2024/024216, filed on Jul. 4, 2024.

(30) Foreign Application Priority Data
Jul. 18, 2023 (JP) 2023-117004

(51) Int. Cl. H10P 50/28; H01J 37/32; H10P 50/00

(52) U.S. Cl. CPC H10P 50/283; H01J 37/32449; H10P 50/73; H01J 2237/334

(57) ABSTRACT

An etching method includes (a) providing a substrate into a chamber. The substrate includes an underlying film, a silicon-containing film on the underlying film, and a mask on the silicon-containing film. The etching method includes (b) etching the silicon-containing film with first plasma generated from a first process gas including a hydrogen fluoride gas and a tungsten-containing gas to form a recess, and (c) etching, after (b), the silicon-containing film further with second plasma generated from a second process gas including a hydrogen fluoride gas. The second process gas is free of a tungsten-containing gas or includes a tungsten-containing gas at a flow rate lower than a flow rate of the tungsten-containing gas in the first process gas.

### CROSS-REFERENCE TO RELATED APPLICATIONS

This application is a Continuation of PCT International Application No. PCT/JP 2024/024216, filed on Jul. 4, 2024, which claims priority under 35 U.S.C. § 119(a) to Patent Application No. JP 2023-117004, filed in Japan on Jul. 18, 2023, all of which are hereby expressly incorporated by reference into the present application.

### FIELD

Exemplary embodiments of the present disclosure relate to an etching method and an etching device.

### BACKGROUND

Patent Literature 1 describes a technique for etching a silicon-containing film included in a substrate using a mask containing amorphous carbon or organic polymers.

### CITATION LIST

### Patent Literature

Patent Literature 1: Japanese Unexamined Patent Application Publication No. 2016-39310

### BRIEF SUMMARY

An etching method according to one exemplary embodiment of the present disclosure includes (a) providing a substrate into a chamber. The substrate includes an underlying film, a silicon-containing film on the underlying film, and a mask on the silicon-containing film. The etching method includes (b) etching the silicon-containing film with first plasma generated from a first process gas including a hydrogen fluoride gas and a tungsten-containing gas to form a recess, and (c) etching, after (b), the silicon-containing film further with second plasma generated from a second process gas including a hydrogen fluoride gas. The second process gas is free of a tungsten-containing gas or includes a tungsten-containing gas at a flow rate lower than a flow rate of the tungsten-containing gas in the first process gas.

### BRIEF DESCRIPTION OF DRAWINGS

FIG. 1 is a diagram of a capacitively coupled plasma processing apparatus illustrating an example structure;

FIG. 2 is a flowchart of an etching method according to one or more embodiments;

FIG. 3 is a diagram of a substrate W showing an example cross-sectional structure;

FIG. 4 is a diagram of the substrate W after step ST12 showing an example cross-sectional structure;

FIG. 5 is a diagram of the substrate W after step ST13 showing an example cross-sectional structure;

FIG. 6 is an example timing chart for an underlying film UF containing silicon;

FIG. 7 is another example timing chart for the underlying film UF containing silicon;

FIG. 8 is an example timing chart for an underlying film containing a metal;

FIG. 9 is a flowchart of an etching method according to one or more embodiments;

FIG. 10 is a graph showing the relationship between ion flux and ion energy;

FIG. 11 is a timing chart of an example source RF signal and an example bias RF signal;

FIG. 12 is a timing chart of an example source RF signal and an example bias DC signal;

FIG. 13 is a flowchart of an etching method according to one or more embodiments;

FIG. 14 is a diagram of a substrate W after step ST32 showing an example cross-sectional structure.

FIG. 15 is a diagram of the substrate W after step ST33 showing an example cross-sectional structure.

FIG. 16 is an example timing chart in one or more embodiments.

### DETAILED DESCRIPTION

One or more embodiments of the present disclosure will now be described. One or more aspects of the present disclosure are directed to a technique for improving etched features.

An etching method according to one exemplary embodiment includes (a) providing a substrate into a chamber. The substrate includes an underlying film, a silicon-containing film on the underlying film, and a mask on the silicon-containing film. The etching method includes (b) etching the silicon-containing film with first plasma generated from a first process gas including a hydrogen fluoride gas and a tungsten-containing gas to form a recess, and (c) etching, after (b), the silicon-containing film further with second plasma generated from a second process gas including a hydrogen fluoride gas. The second process gas is free of a tungsten-containing gas or includes a tungsten-containing gas at a flow rate lower than a flow rate of the tungsten-containing gas in the first process gas.

In one exemplary embodiment, the tungsten-containing gas includes WF6.

In one exemplary embodiment, the first process gas further includes a phosphorus-containing gas.

In one exemplary embodiment, the second process gas is free of a phosphorus-containing gas or includes a phosphorus-containing gas at a flow rate lower than a flow rate of the phosphorus-containing gas in the first process gas.

In one exemplary embodiment, the second process gas further includes a xenon gas.

In one exemplary embodiment, the first process gas is free of a xenon gas or includes a xenon gas at a flow rate lower than a flow rate of the xenon gas in the second process gas.

In one exemplary embodiment, (b) is performed until before the underlying film is exposed at the recess or until the underlying film is at least partly exposed at the recess.

In one exemplary embodiment, (b) is performed until the underlying film is partly etched.

In one exemplary embodiment, a plurality of cycles each including (b) and (c) are performed.

In one exemplary embodiment, while the silicon-containing film is being etched in (b), a first protrusion and a second protrusion form on the mask, the first protrusion is at a first position to reduce a width of an opening in the mask, and the second protrusion is at a second position below the first position to reduce the width of the opening in the mask.

In one exemplary embodiment, (b) includes forming a flared recess in the silicon-containing film, and (c) includes etching the silicon-containing film to change a feature of the flared recess to a rectangle.

An etching method according to one exemplary embodiment includes (a) providing a substrate into a chamber. The substrate includes an underlying film, a silicon-containing film on the underlying film, and a mask on the silicon-containing film. The etching method includes (b) etching the silicon-containing film with first plasma generated from a first process gas to form a recess, and (c) etching, after (b), the silicon-containing film further with second plasma generated from a second process gas. The first process gas includes a single gas or a mixed gas including fluorine and hydrogen, and a metal-containing gas. The second process gas includes a single gas or a mixed gas including fluorine and hydrogen. The second process gas is free of the metal-containing gas or includes the metal-containing gas at a flow rate lower than a flow rate of the metal-containing gas in the first process gas.

In one exemplary embodiment, the metal-containing gas includes at least one metal selected from the group consisting of tungsten, molybdenum, titanium, and ruthenium.

In one exemplary embodiment, the first process gas further includes a phosphorus-containing gas.

In one exemplary embodiment, the second process gas is free of a phosphorus-containing gas or includes a phosphorus-containing gas at a flow rate lower than a flow rate of the phosphorus-containing gas in the first process gas.

In one exemplary embodiment, the second process gas further includes a noble gas. The noble gas includes at least one selected from the group consisting of an argon gas, a krypton gas, a xenon gas, and a radon gas.

In one exemplary embodiment, the first process gas is free of the noble gas or includes the noble gas at a flow rate lower than a flow rate of the noble gas in the second process gas.

An etching device according to one exemplary embodiment includes a chamber, a substrate support in the chamber, a plasma generator, and a controller that controls the plasma generator to perform processes including (a) providing a substrate into the chamber. The substrate includes an underlying film, a silicon-containing film on the underlying film, and a mask on the silicon-containing film. The processes include (b) etching the silicon-containing film with first plasma generated from a first process gas including a hydrogen fluoride gas and a tungsten-containing gas to form a recess, and (c) etching, after (b), the silicon-containing film further with second plasma generated from a second process gas including a hydrogen fluoride gas. The second process gas is free of the tungsten-containing gas or includes the tungsten-containing gas at a flow rate lower than a flow rate of the tungsten-containing gas in the first process gas.

One or more embodiments of the present disclosure will now be described with reference to the drawings. In the drawings, the same reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example Structure of Plasma Processing System

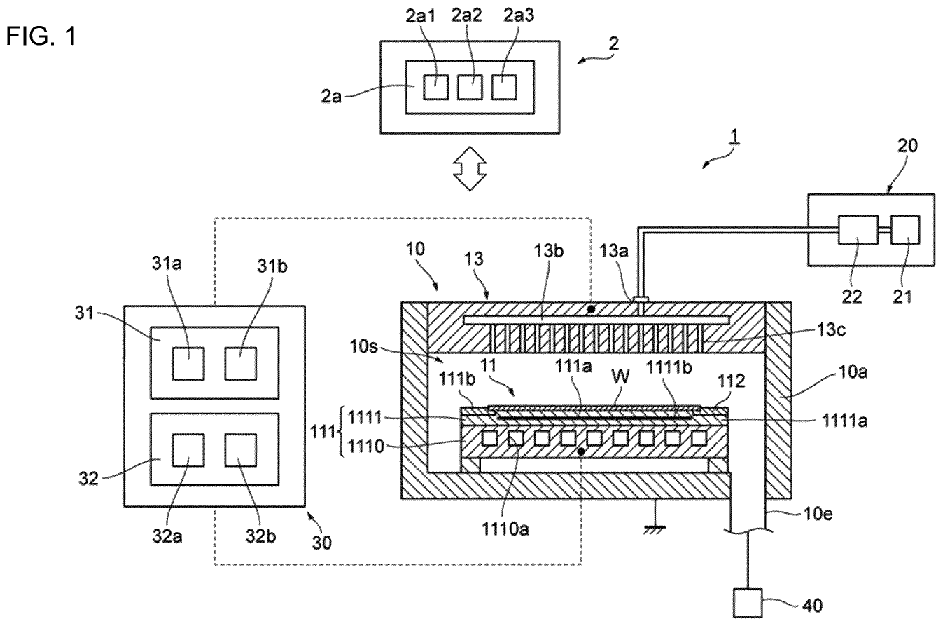

An example structure of a plasma processing system will now be described. FIG. 1 is a diagram of a capacitively coupled plasma processing apparatus illustrating an example structure.

The plasma processing system includes a capacitively coupled plasma processing apparatus 1 and a controller 2. The capacitively coupled plasma processing apparatus 1 includes a plasma processing chamber 10, a gas supply 20, a power supply 30, and an exhaust system 40. The plasma processing apparatus 1 further includes a substrate support 11 and a gas guide unit. The gas guide unit allows at least one process gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 has at least one gas inlet for supplying at least one process gas into the plasma processing space 10s and at least one gas outlet for discharging the gas from the plasma processing space. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located in the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular E′SC or an annular insulating member. In this case, the ring assembly 112 may be located on the annular ESC or the annular insulating member, or may be located on both the ESC 1111 and the annular insulating member. At least one radio frequency (RF)/direct current (DC) electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one process gas from the gas supply 20 into the plasma processing space 10s. The showerhead 13 includes at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The showerhead 13 further includes at least one upper electrode. In addition to the showerhead 13, the gas guide unit may include one or more side gas injectors (SGIs) installed in one or more openings in the sidewall 10a.

The gas supply 20 may include at least one gas source 21 and at least one flow controller 22. In one embodiment, the gas supply 20 supplies at least one process gas from each gas source 21 to the showerhead 13 through the corresponding flow controller 22. The flow controller 22 may be, for example, a mass flow controller or a pressure-based flow controller. The gas supply 20 may further include one or more flow rate modulators that cause at least one process gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates plasma from at least one process gas supplied into the plasma processing space 10s. The RF power supply 31 may thus function as at least a part of a plasma generator that generates plasma from one or more process gases in the plasma processing chamber 10. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode as a first bias DC signal. In one embodiment, the second DC generator 32b is coupled to at least one upper electrode to generate a second DC signal. The generated second DC signal is applied to at least one upper electrode.

In various embodiments, at least one of the first DC signal or the second DC signal may be pulsed. In this case, a sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

The controller 2 processes computer-executable instructions that cause the plasma processing apparatus 1 to perform various steps described in one or more embodiments of the present disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a 1, a storage 2a2, and a communication interface 2a 3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a 1. The medium may be one of various storage media readable by the computer 2a or a communication line connected to the communication interface 2a 3. The processor 2a 1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### One or More Embodiments

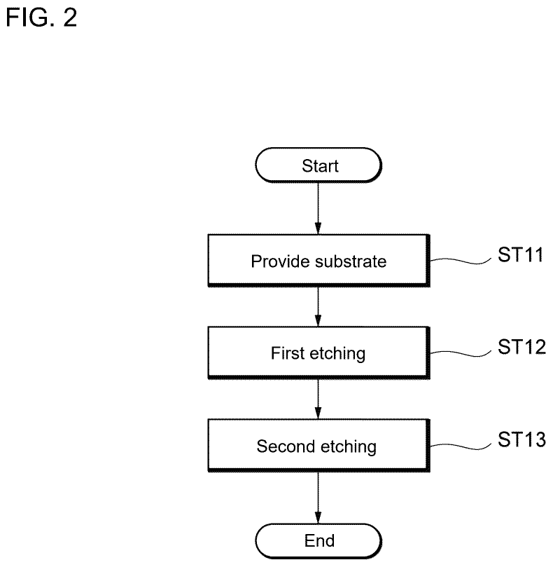

FIG. 2 is a flowchart of an etching method according to one or more embodiments. As shown in FIG. 2, the etching method includes step ST11 for providing a substrate, first etching step ST12, and second etching step ST13. The processing in each of steps ST11 to ST13 may be performed by the plasma processing system shown in FIG. 1. In other words, the etching method according to one or more embodiments may be performed using the plasma processing apparatus 1 as an etching device. The etching method according to one or more embodiments will now be described using an example in which the controller 2 controls the components of the plasma processing apparatus 1 to etch a substrate W.

### Step ST11: Providing Substrate

In step ST11, the substrate W is provided into the plasma processing space 10s of the plasma processing apparatus 1. The substrate W is provided to the central portion 111a of the substrate support 11. The substrate W is held on the substrate support 11 by the ESC 1111.

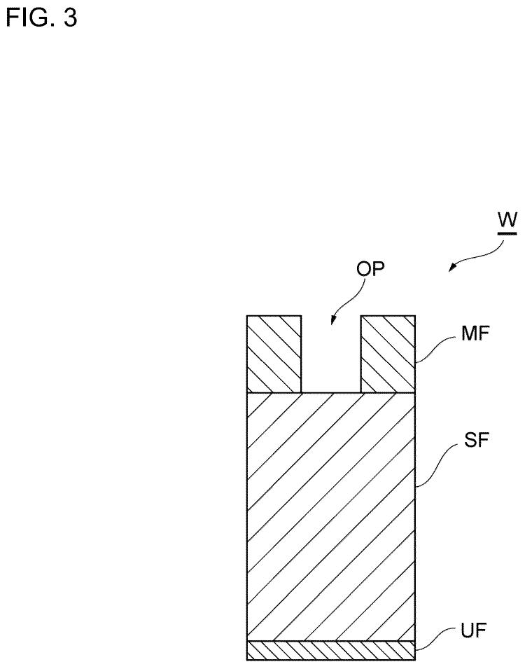

FIG. 3 is a diagram of the substrate W showing an example cross-sectional structure. In step ST11, the substrate W shown in FIG. 3 may be provided. The substrate W includes, as an etching target film, a silicon-containing film SF on an underlying film UF. The substrate W may further include a mask MF on the silicon-containing film SF. The substrate W may be used for manufacturing semiconductor devices. Examples of the semiconductor devices include semiconductor memory devices such as a dynamic RAM (DRAM) and a three-dimensional NOT-AND (3D-NAND) flash memory.

The underlying film UF may be, for example, a silicon wafer, or an organic film, a dielectric film, a metal film, or a semiconductor film on the silicon wafer. The underlying film UF may be a stack of multiple films. The underlying film UF may contain a metal such as silicon or tungsten.

The silicon-containing film SF is a target film for etching. Examples of the silicon-containing film SF include a silicon oxide film, a silicon nitride film, a silicon oxynitride film, a polycrystalline silicon film, and a carbon-containing silicon film. The silicon-containing film SF may be a stack of multiple films. For example, the silicon-containing film SF may include alternately stacked silicon oxide films and silicon nitride films. In another example, the silicon-containing film SF may include alternately stacked silicon oxide films and polycrystalline silicon films. In another example, the silicon-containing film SF may be a stack of films including a silicon nitride film, a silicon oxide film, and a polycrystalline silicon film.

The mask MF is a film that masks the silicon-containing film SF in etching. The mask MF may be, for example, a hard mask. The mask MF may be, for example, a carbon-containing mask or a metal-containing mask, or both. The carbon-containing mask may be formed from, for example, at least one selected from the group consisting of spin-on carbon, tungsten carbide, amorphous carbon, and boron carbide. The metal-containing mask may be formed from, for example, at least one selected from the group consisting of titanium nitride, titanium oxide, and tungsten. The tungsten-containing mask may be formed from, for example, tungsten silicide (WSi) or tungsten carbide (WC), or both. The mask MF may be a boron-containing mask formed from, for example, silicon boride, boron nitride, or boron carbide.

As shown in FIG. 3, the mask MF defines at least one opening OP on the silicon-containing film SF. The opening OP is a space on the silicon-containing film SF, surrounded by a sidewall of the mask MF. In other words, the upper surface of the silicon-containing film SF includes a portion covered with the mask MF and a portion exposed on the bottom of the opening OP.

The opening OP may have any feature in a plan view of the substrate W, or in other words, when the substrate W is viewed from the top to the bottom in FIG. 3. The opening feature may be, for example, a circle, an oval, a rectangle, a line, or a combination of one or more of these. The mask MF may have multiple sidewalls, which may define multiple openings OP. The multiple openings OP may be slits arranged in a pattern of lines and spaces at regular intervals. The multiple openings OP may be holes in a patterned array.

The films included in the substrate W (the underlying film UF, the silicon-containing film SF, and the mask MF) may each be formed by chemical vapor deposition (CVD), atomic layer deposition (ALD), spin coating, or other methods. The opening OP may be formed by etching the mask MF. The mask MF may be formed by lithography. Each film may be a flat film or an uneven film. The substrate W may further include another film under the underlying film UF. The stacked films of the silicon-containing film SF and the underlying film UF may then serve as a multilayer mask. In other words, the stacked films of the silicon-containing film SF and the underlying film UF may be used as a multilayer mask to etch the other film.

The processing for forming each film included in the substrate W may be at least partly performed in the space of the plasma processing chamber 10. In one example, the step of etching the mask MF to form the opening OP may be performed in the plasma processing chamber 10. In other words, the etching of the opening OP and the etching of the silicon-containing film SF (described later) may be sequentially performed in the same chamber. All or some of the films included in the substrate W may be formed in a device or a chamber external to the plasma processing apparatus 1. The resultant substrate W may then be loaded into the plasma processing space 10s of the plasma processing apparatus 1 and placed on the central portion 111a of the substrate support 11 to be provided into the plasma processing space 10s.

After the substrate W is provided to the central portion 111a of the substrate support 11, the temperature of the substrate support 11 is adjusted to a set temperature by the temperature controller. The set temperature may be, for example, 20° C. or lower, 0 ° C. or lower, −10 °C or lower, −20 °C. or lower, −30 °C. or lower, −40 °C. or lower, −50 °C. or lower, −60 °C. or lower, or −70 °C. or lower. In one example, adjusting or maintaining the temperature of the substrate support 11 includes causing the temperature of the heat transfer fluid flowing through the channel 1110a and the temperature of the heater to be the respective set temperatures, or to be temperatures different from the respective set temperatures. The heat transfer fluid may start to flow through the channel 1110a before, after, or at the same time as the substrate W is placed on the substrate support 11. The temperature of the substrate support 11 may be adjusted to the set temperature before step ST11. In other words, the substrate W may be provided to the substrate support 11 after the temperature of the substrate support 11 is adjusted to the set temperature.

### Step ST12: First Etching

In step ST12, the silicon-containing film SF is etched using plasma generated from a first process gas. The gas supply 20 first supplies the first process gas into the plasma processing space 10s. The first process includes a hydrogen fluoride (HF) gas. The HF gas functions as an etchant. During the processing in step ST12, the temperature of the substrate support 11 is maintained at the set temperature adjusted in step ST11.

A source RF signal is then provided to the lower electrode of the substrate support 11 or the upper electrode of the showerhead 13, or both. This generates an RF electric field between the showerhead 13 and the substrate support 11 and generates first plasma from the first process gas in the plasma processing space 10s. A bias signal is provided to the lower electrode of the substrate support 11 to generate a bias potential difference between the plasma and the substrate W. The bias potential difference causes active species such as ions and radicals in the plasma to be attracted toward the substrate W. This etches the silicon-containing film SF, forming a recess in the silicon-containing film SF based on the feature of the opening OP in the mask MF. The first etching may be performed until before (e.g., immediately before) the underlying film UF is exposed or until the underlying film UF is at least partly exposed. More specifically, step ST12 may be ended before (or immediately before) the underlying film UF in the substrate W is exposed or when the underlying film UF is at least partly exposed.

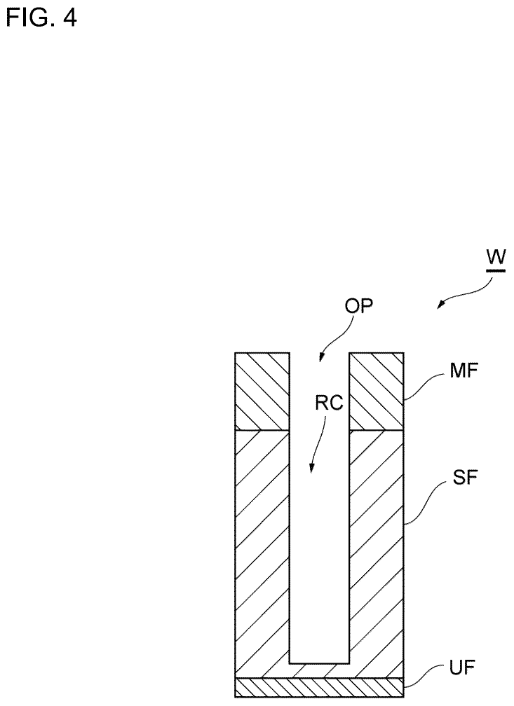

FIG. 4 is a diagram of the substrate W after step ST12 showing an example cross-sectional structure. As shown in FIG. 4, the processing in step ST12 etches the portion of the silicon-containing film SF exposed through the opening OP in the depth direction (from the top to the bottom in FIG. 4), forming a recess RC. In FIG. 4, the underlying film UF is unexposed after step ST12. More specifically, step ST12 may be stopped with the silicon-containing film SF partly left between the underlying film UF and the bottom of the recess RC. Step ST13 may be started in this state and may be performed for a period including the time at which the underlying film UF is exposed. In some embodiments, the underlying film UF may be at least partly exposed at the recess RC after step ST12. Multiple cycles each including steps ST12 and ST13 may be performed until the underlying film UF is exposed or until the underlying film UF is partly etched.

In step ST12, the source RF signal may have a frequency ranging from 10 to 150 MHz. In one example, the source RF signal may have a frequency of 40 MHz or higher, or 60 MHz or higher. In step ST12, the bias signal may be the bias RF signal provided from the second RF generator 31b. The bias signal may be the bias DC signal (e.g., a sequence of voltage pulses) provided from the DC generator 32a. Both the source RF signal and the bias signal may be continuous waves or pulsed waves, or one of the source RF signal or the bias signal may be continuous waves and the other may be pulsed waves. When both the source RF signal and the bias signal are pulsed waves, the cycles of the two pulsed waves may be synchronized. The duty cycle of the pulsed waves may be set as appropriate, and may be, for example, 1 to 80% or 5 to 50%. The duty cycle is the percentage of the period in which the level of power or voltage is higher in a pulse wave cycle. When the bias DC signal is used, the voltage pulses in the sequence may have rectangular, trapezoidal, or triangular pulse waveforms, or a combination of these. The bias DC signal may have negative or positive polarity, and may adjust the potential of the substrate W to create a potential difference between the plasma and the substrate to draw ions.

In step ST12, the HF gas included in the first process gas may have the highest flow rate (partial pressure) among the gases in the first process gas (among all the gases in the first process gas excluding an inert gas when the first process gas includes an inert gas). In one example, the flow rate of the HF gas may be higher than or equal to 50, 60, 70, 80, 90, or 95 vol % relative to the total flow rate of the first process gas (the total flow rate of all the gases in the first process gas excluding an inert gas when the first process gas includes an inert gas). The flow rate of the HF gas may be less than 100 vol%, 99.5 vol% or less, 98 vol% or less, or 96 vol % or less relative to the total flow rate of the first process gas. In one example, the flow rate of the HF gas is adjusted to be 70 to 96 vol% inclusive relative to the total flow rate of the first process gas.

The first process gas may further include at least one selected from the group consisting of a carbon-containing gas, an oxygen-containing gas, and a phosphorus-containing gas.

The carbon-containing gas may be, for example, either a fluorocarbon gas or a hydrofluorocarbon gas, or both. In one example, the fluorocarbon gas may be at least one selected from the group consisting of a CF4 gas, a C2F2 gas, a C2F4 gas, a C3F6 gas, a C3F8 gas, a C4F6 gas, a C4F8 gas, and a C5F8 gas. In one example, the hydrofluorocarbon gas may be at least one selected from the group consisting of a CHF3 gas, a CH2F2 gas, a CH3F gas, a C2HF5 gas, a C2H2F4 gas, a C2H3F3 gas, a C2H4F2 gas, a C3HF7 gas, a C3H2F2 gas, a C3H2F4 gas, a C3H2F6 gas, a C3H3F5 gas, a C4H2F6 gas, a C4H5F5 gas, a C4H2F8 gas, a C5H2F6 gas, a C5H2F10 gas, and a C5H3F7 gas. The carbon-containing gas may have a linear chain structure with unsaturated bonds. The linear carbon-containing gas with unsaturated bonds may be, for example, at least one selected from the group consisting of a hexafluoropropene (C3F6) gas, an octafluoro-1-butene, octafluoro-2-butene (C4F8) gas, a 1,3,3,3-tetrafluoropropene (C3H2F4) gas, a trans-1,1,1,4,4,4-hexafluoro-2-butene (C4H2F 6) gas, a pentafluoroethyl trifluorovinyl ether (C4F8O) gas, a 1,2,2,2-tetrafluoroethane-1-one (CF3COF) gas, a difluoroacetic acid fluoride (CHF2COF) gas, and a carbonyl fluoride (COF2) gas.

The oxygen-containing gas may be, for example, at least one gas selected from the group consisting of O2, CO, CO2, H2O, and H2O2. In one example, the oxygen-containing gas may be at least one gas selected from the group consisting of oxygen-containing gases other than H2O, or specifically, O2, CO, CO2, and H2O2. The flow rate of the oxygen-containing gas may be adjusted based on the flow rate of the carbon-containing gas.

The phosphorus-containing gas includes a phosphorus-containing molecule. The phosphorus-containing molecule may be an oxide such as tetraphosphorus decaoxide (P4O10), tetraphosphorus octoxide (P4O8), or tetraphosphorus hexaoxide (P4O6). Tetraphosphorus decaoxide may also be referred to as diphosphorus pentaoxide (P2O5). The phosphorus-containing molecule may be a halide (phosphorus halide) such as phosphorus trifluoride (PF3), phosphorus pentafluoride (PF5), phosphorus trichloride (PCl3), phosphorus pentachloride (PCl5), phosphorus tribromide (PBr3), phosphorus pentabromide (PBr5), or phosphorus iodide (PI3). In other words, the halogen included in the phosphorus-containing molecule may be fluorine in, for example, a phosphorus fluoride. In some embodiments, the phosphorus-containing molecule may include a non-fluorine halogen. The phosphorus-containing molecule may be a phosphoryl halide such as phosphoryl fluoride (POF3), phosphoryl chloride (POCl3), or phosphoryl bromide (POBr3). The phosphorus-containing molecule may be phosphine (PH3), calcium phosphide (e.g., Ca3P2), phosphoric acid (H3PO4), sodium phosphate (Na3PO4), or hexafluorophosphoric acid (HPF6). The phosphorus-containing molecule may be a fluorophosphine (HgPFh), where the sum of g and h is 3 or 5. The fluorophosphine may be, for example, HPF2 or H2PF3. The process gas may include at least one phosphorus-containing molecule selected from the above phosphorus-containing molecules. For example, the process gas may include at least one phosphorus-containing molecule selected from the group consisting of PF3, PCl3, PF5, PCl5, POCl3, PH3, PBr3, and PBr5. Each phosphorus-containing molecule in the process gas in liquid or solid form may be vaporized by, for example, heating before being supplied into the plasma processing space 10s.

The phosphorus-containing gas may be a PClaFb gas (where a is an integer greater than or equal to 1, b is an integer greater than or equal to 0, and the sum of a and b is an integer less than or equal to 5) or a PCcHdFe gas (where d and e are integers of 1 to 5 inclusive, and c is an integer of 0 to 9 inclusive).

The PClaFb gas may be, for example, at least one gas selected from the group consisting of a PClF2 gas, a PCl2F gas, and a PCl2F3 gas.

The PCcHdFe gas may be, for example, at least one gas selected from the group consisting of a PF2CH3 gas, a PF(CH3)2 gas, a PH2CF3 gas, a PH(CF3)2 gas, a PCH3(CF3)2 gas, a PH2F gas, and a PF3(CH3)2 gas.

The phosphorus-containing gas may be a PClcFdCeHf gas (where c, d, e, and f are integers greater than or equal to 1). The phosphorus-containing gas may be a gas including phosphorus (P), fluorine (F), and a halogen other than F (e.g., Cl, Br, or I) in its molecular structure, a gas including P, F, carbon (C), and hydrogen (H) in its molecular structure, or a gas including P, F, and H in its molecular structure.

The phosphorus-containing gas may be a phosphine gas. Examples of the phosphine gas include phosphine (PH3), compounds resulting from substituting at least one hydrogen atom of phosphine with an appropriate substituent, and phosphinic acid derivatives.

Examples of the substituent for substituting the hydrogen atoms of phosphine include, but are not limited to, fluorine atoms, halogen atoms such as chlorine atoms, alkyl groups such as methyl groups, ethyl groups, and propyl groups, and hydroxyalkyl groups such as hydroxymethyl groups, hydroxyethyl groups, and hydroxypropyl groups. In one example, chlorine atoms, methyl groups, or hydroxymethyl groups may be used.

Examples of the phosphinic acid derivatives include phosphinic acid (H3O2P), alkyl phosphinic acid (PHO(OH)R), and dialkyl phosphinic acid (PO(OH)R2).

The phosphine gas may be, for example, at least one gas selected from the group consisting of a dichloro(methyl)phosphine (PCH3Cl2) gas, a chloro(dimethyl)phosphine (P(CH3)2Cl) gas, a dichloro(hydroxymethyl)phosphine (P(HOCH2)Cl2) gas, a chloro(dihydroxylmethyl)phosphine (P(HOCH2)2Cl) gas, a dimethyl(hydroxylmethyl)phosphine (P(HOCH2)(CH3)2) gas, a methyl(dihydroxylmethyl)phosphine (P(HOCH2)2(CH3)) gas, a tris(hydroxylmethyl)phosphine (P(HOCH2)3) gas, a phosphinic acid (H3O2P) gas, a methyl phosphinic acid (PHO(OH)(CH3)) gas, and a dimethyl phosphinic acid (PO(OH)(CH3)2) gas.

The flow rate of the phosphorus-containing gas included in the first process gas may be less than or equal to 20, 10, or 5 vol % relative to the total flow rate of the first process gas excluding the flow rate of an inert gas.

The first process gas may further include a tungsten-containing gas (W-containing gas). The tungsten-containing gas may contain tungsten and halogen. In one example, the tungsten-containing gas is a WFxCly gas (x and y are integers of 0 to 6 inclusive, and the sum of x and y is 2 to 6 inclusive). More specifically, the tungsten-containing gas may be one or more of a gas containing tungsten and fluorine, such as a tungsten difluoride (WF2) gas, a tungsten tetrafluoride (WF4) gas, a tungsten pentafluoride (WF5) gas, or a tungsten hexafluoride (WF6) gas or a gas containing tungsten and chlorine, such as a tungsten dichloride (WCl2) gas, a tungsten tetrachloride (WCl4) gas, a tungsten pentachloride (WCl5) gas, or a tungsten hexachloride (WCl6) gas. Among these, the tungsten-containing gas may be at least one of a WF6 gas or a WCl6 gas. The first process gas may include a titanium-containing gas or a molybdenum-containing gas, in place of or in addition to the tungsten-containing gas. In other words, the first process gas may include at least one metal-containing gas. The metal-containing gas may include at least one metal selected from the group consisting of tungsten, molybdenum, titanium, and ruthenium.

The first process gas may further include a halogen-containing gas. The first process gas may further include a gas containing a halogen other than fluorine, or specifically, a fluorine-free halogen-containing gas, or a halogen-containing gas containing fluorine, or both. The gas containing a halogen other than fluorine may be at least one of a chlorine-containing gas, a bromine-containing gas, or an iodine-containing gas. In one example, the chlorine-containing gas may be at least one gas selected from the group consisting of Cl2, SiCl2, SiCl4, CCl4, SiH2Cl2, Si2Cl6, CHCl3, SO2Cl2, BCl3, PCl3, PCl5, and POCl3. In one example, the bromine-containing gas may be at least one gas selected from the group consisting of Br2, HBr, CBr2F2, C2F5Br, PBr3, PBr5, POBr3, and BBr3. In one example, the iodine-containing gas may be at least one gas selected from the group consisting of HI, CF3I, C2F5I, C3F7I, IF5, IF7, I2, and PI3. In one example, the gas containing a halogen other than fluorine may be at least one selected from the group consisting of a Cl2 gas, a Br2 gas, and an HBr gas. In one example, the gas containing a halogen other than fluorine is a Cl2 gas or an HBr gas. The halogen-containing gas containing fluorine may include a nitrogen trifluoride (NF3) gas or a sulfur hexafluoride (SF6) gas, or both.

The first process gas may further include an inert gas. The inert gas may be, for example, a noble gas or a nitrogen gas, or both. Examples of the noble gas include an Ar gas, a He gas, a Ne gas, a Kr gas, a Xe gas, and a Rn gas.

The first process gas may include, in place of part or all of the HF gas, a gas that can generate an HF species in the first plasma. The HF species includes at least any of a gas, radicals, or ions of HF.

The gas that can generate an HF species may be a single gas or a mixed gas including fluorine and hydrogen. The single gas including fluorine and hydrogen may be, for example, a hydrofluorocarbon gas. The hydrofluorocarbon gas may have two or more, three or more, or four or more carbon atoms. In one example, the hydrofluorocarbon gas is at least one selected from the group consisting of a CH2F2 gas, a C3H2F4 gas, a C3H2F6 gas, a C3H3F5 gas, a C4H2F6 gas, a C4H5F5 gas, a C4H2F8 gas, a C5H2F6 gas, a C5H2F10 gas, and a C5H3F7 gas. In one example, the hydrofluorocarbon gas is at least one selected from the group consisting of a CH2F2 gas, a C3H2F4 gas, a C3H2F6 gas, and a C4H2F6 gas.

The hydrogen source in the mixed gas including fluorine and hydrogen may be, for example, at least one selected from the group consisting of an H2 gas, an NH3 gas, an H2O gas, an H2O2 gas, and a hydrocarbon gas (e.g., a CH4 gas or a C3H6 gas). The fluorine source may be a carbon-free fluorine-containing gas, such as an NF3 gas, an SF6 gas, a WF6 gas, or an XeF2gas. The fluorine source may be a fluorine-containing gas including carbon, such as a fluorocarbon gas or a hydrofluorocarbon gas. The fluorocarbon gas may be, for example, at least one selected from the group consisting of a CF4 gas, a C2F2 gas, a C2F4 gas, a C3F6 gas, a C3F8 gas, a C4F6 gas, a C4F8 gas, and a C5F8 gas. In one example, the hydrofluorocarbon gas is at least one selected from the group consisting of a CHF3 gas, a CH2F2 gas, a CH3F gas, a C2HF5 gas, and a hydrofluorocarbon gas having three or more carbon atoms (e.g., a C3H2F4 gas, a C3H2F6 gas, or a C4H2F6 gas).

### Step ST13: Second Etching

Second etching step ST13 is performed subsequently to first etching step ST12. Second etching step ST13 may be started before the recess RC reaches the underlying film UF. More specifically, step ST13 may be started with the silicon-containing film SF partly left between the underlying film UF and the bottom of the recess RC, and may be performed for a period including the time at which the underlying film UF is exposed. In some embodiments, second etching step ST13 may be started when the underlying film UF is at least partly exposed at the recess. Step ST12 is shifted to step ST13 based on at least one of the depth of the recess RC, the aspect ratio of the recess RC, or an etching duration.

In step ST13, the gas supply 20 first supplies a second process gas into the plasma processing space 10s. In step ST13, a source RF signal is provided to the lower electrode of the substrate support 11 or the upper electrode of the showerhead 13, or both, as in step ST12. This generates an RF electric field between the showerhead 13 and the substrate support 11 to generate second plasma from the second process gas in the plasma processing space 10s. In step ST13, a bias signal is provided to the lower electrode of the substrate support 11 to generate a bias potential between the plasma and the substrate W. The bias potential attracts active species such as ions and radicals in the plasma toward the substrate W. The active species further etches the silicon-containing film SF. Step ST13 is performed until the underlying film UF is exposed or until the underlying film UF is at least partly etched in the depth direction. During the processing in step ST12, the temperature of the substrate support 11 may be maintained at the set temperature adjusted in step ST11, or may be changed as described later.

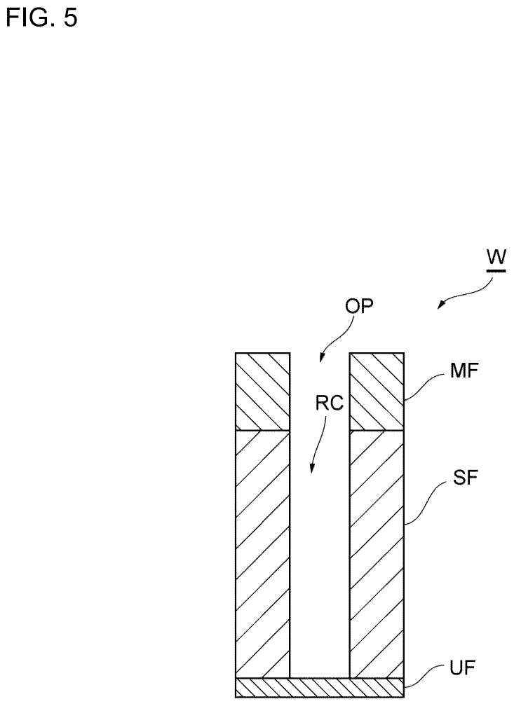

FIG. 5 is a diagram of the substrate W after step ST13 showing an example cross-sectional structure. As shown in FIG. 5, the substrate W processed in step ST13 has the bottom of the recess RC reaching the underlying film UF, with the underlying film UF being exposed. In this state, the underlying film UF may be partly etched in the depth direction. The recess RC in this state may have an aspect ratio of, for example, 20 or more, 30 or more, 40 or more, 50 or more, or 100 or more.

In step ST13, the second process gas may include the same or different types of gases as or from the first process gas. The second process gas may include, for example, an HF gas. The second process gas may further include, for example, at least one selected from the group consisting of the carbon-containing gas, the oxygen-containing gas, and the phosphorus-containing gas described above. The second process gas may further include, for example, the tungsten-containing gas, the titanium-containing gas, the molybdenum-containing gas, the inert gas, and the halogen-containing gas described above. The second process gas may include, in place of part or all of the HF gas, a gas that can generate an HF species in the second plasma, similarly to the first process gas.

In step ST13, the source RF signal may have a frequency ranging from 10 to 150 MHz. In one example, the source RF signal may have a frequency of 40 MHz or higher or 60 MHz or higher. In step ST13, the bias signal may be the bias RF signal provided from the second RF generator 31b. The bias signal may be the bias DC signal (e.g., a sequence of voltage pulses) provided from the DC generator 32a. Both the source RF signal and the bias signal may be continuous waves or pulsed waves, or one of the source RF signal or the bias signal may be continuous waves and the other may be pulsed waves. When both the source RF signal and the bias signal are pulsed waves, the cycles of the two pulsed waves may be synchronized. The duty cycle of the pulsed waves may be set as appropriate, and may be, for example, 1 to 80% or 5 to 50%. The duty cycle is the percentage of the period in which the level of power or voltage is higher in a pulse wave cycle. When the bias DC signal is used, the voltage pulses in the sequence may have rectangular, trapezoidal, or triangular pulse waveforms, or a combination of these. The bias DC signal may have negative or positive polarity for each voltage pulse, and may adjust the potential of the substrate W to create a potential difference between the plasma and the substrate to draw ions. The source RF signal or the bias signal, or both may be provided continuously from step ST12. The source RF signal or the bias signal, or both may be stopped at the end of step ST12, and may be started again at the start of step ST13.

When step ST13 is started, the processing conditions for etching are changed from those in step ST12 (recipe 1) to those in step ST13 (recipe 2). In other words, in step ST13, the silicon-containing film SF is etched using a recipe different from the recipe in step ST12. The recipe change may include using the second process gas different from the first process gas and/or performing temperature control to increase the temperature of the substrate W to be higher than in step ST12. In one example, the processing conditions in step ST13 (recipe 2) may include improving the selectivity of the silicon-containing film SF over the underlying film UF further than with the processing conditions in step ST12 (recipe 1). In this case, the processing conditions in step ST13 (recipe 2) may be selected as appropriate for the type of the underlying film UF. For example, the processing conditions may differ between an underlying film UF containing silicon and an underlying film UF containing a metal. The recipe change may also include lowering the process pressure (the pressure in the chamber during processing). In other words, in step ST13, the pressure in the plasma processing space 10s may be lower than in step ST12. For example, the pressure in the plasma processing space 10s in step ST13 may be lower than in step ST12 by at least 30%.

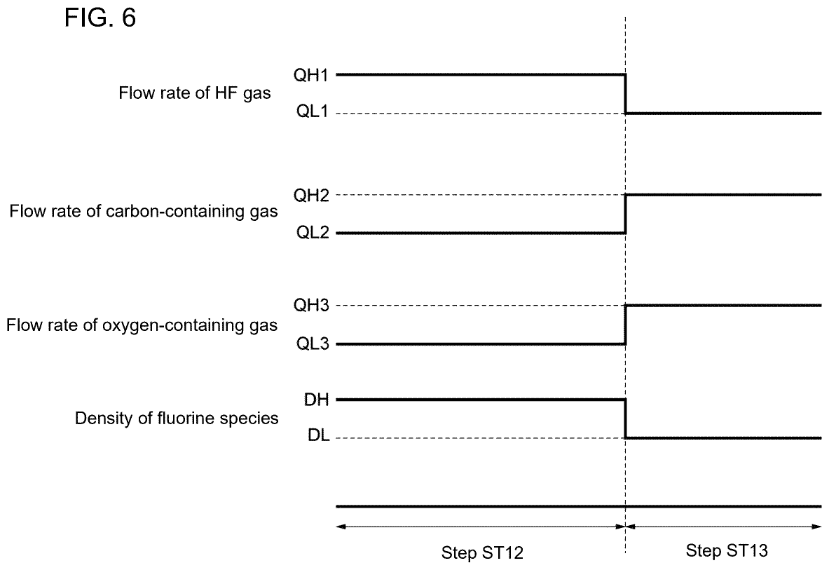

FIG. 6 is an example timing chart for the underlying film UF containing silicon. In the example shown in FIG. 6, steps ST12 and ST13 use process gases having different compositions. In FIG. 6, the horizontal axis indicates time. The vertical axis indicates the flow rates of the HF gas, the carbon-containing gas, and the oxygen-containing gas included in the process gas (the first process gas or the second process gas), and the density of the fluorine species in the plasma (the first plasma or the second plasma). The flow rates QL1, QL2, and QL3 are lower than the flow rates QH1, QH2, and QH3 or are zero. The density DL of the fluorine species in plasma is lower than the density DH of the fluorine species in plasma. In FIG. 6, the carbon-containing gas is a fluorocarbon gas or a hydrofluorocarbon gas, or both. For the carbon-containing gas being both a fluorocarbon gas and a hydrofluorocarbon gas, the flow rate of the carbon-containing gas is the sum of the flow rates of the fluorocarbon gas and the hydrofluorocarbon gas. The fluorine species is an active species of fluorine dissociated from the fluorine-containing gas (e.g., an HF gas, a fluorocarbon gas, a hydrofluorocarbon gas, an NF3 gas, or a SF6 gas) in the process gas.

As shown in FIG. 6, when the underlying film UF contains silicon, the flow rate (partial pressure) of the HF gas may be lowered and the flow rate (partial pressure) of each of the carbon-containing gas (a fluorocarbon gas or a hydrofluorocarbon gas, or both) and the oxygen-containing gas may be increased upon the shift from step ST12 to step ST13. In one example, upon the shift from step ST12 to step ST13, the process gas (second process gas) may include the carbon-containing gas and the oxygen-containing gas at a flow rate of 50 vol % or greater relative to the total flow rate of the second process gas excluding the flow rate of the inert gas. The fluorocarbon gas or the hydrofluorocarbon gas, or both included in the second process gas may have two or more carbon atoms.

The underlying film UF is exposed as etching in step ST13 proceeds. For the underlying film UF containing silicon, the fluorine species in the plasma also serves as an etchant for the underlying film UF. In the example shown in the timing chart in FIG. 6, the density of the fluorine species in the second plasma generated in step ST13 is lower than the density of the fluorine species in the first plasma generated in step ST12. This reduces etching of the underlying film UF. In other words, this can improve the selectivity of the silicon-containing film SF over the underlying film UF in etching.

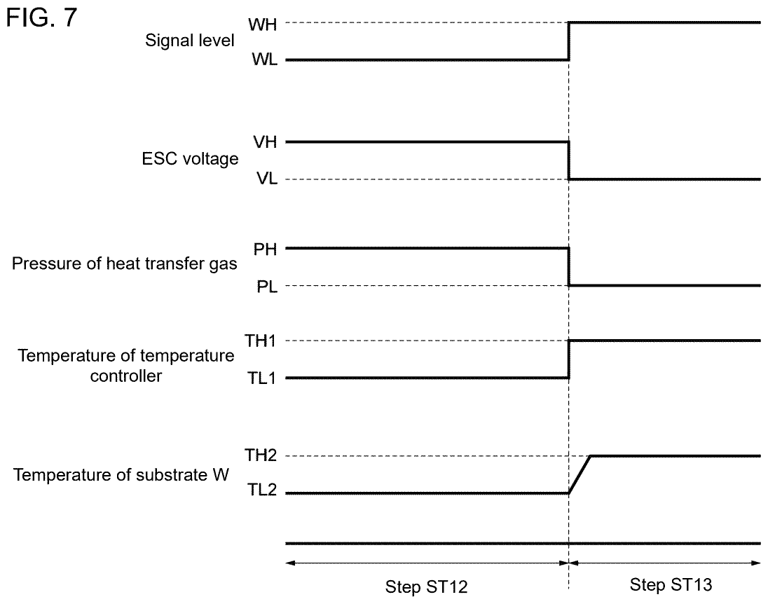

FIG. 7 is another example timing chart for the underlying film UF containing silicon. FIG. 7 shows an example of controlling the temperature of the substrate W in step ST12 to rise in step ST13. In FIG. 7, the horizontal axis indicates time. The vertical axis indicates the signal level, the DC voltage to be applied to the ESC 1111 (ESC voltage), the pressure of the heat transfer gas (e.g., He) to be supplied to the space between the ESC 1111 and the back surface of the substrate W, the temperature of the heater or the temperature of the heat transfer fluid flowing through the channel 1110a, or both (the temperature of the temperature controller), and the temperature of the substrate W. The signal level is the power level of the source RF signal or the level of the bias signal (the power level of the bias RF signal or the absolute value of the voltage level of the voltage pulse), or both. In FIG. 7, the signal level WL is lower than the signal level WH. The ESC voltage VL is lower than the ESC voltage VH. The pressure PL of the heat transfer gas is lower than the pressure PH. The temperature TL1 is lower than the temperature TH1, and the temperature TL2 is lower than the temperature TH2.

As shown in FIG. 7, when the underlying film UF contains silicon, (I) the signal level of the source RF signal or the signal level of the bias signal, or both may be increased upon the shift from step ST12 to step ST13. Increasing the signal level may include increasing the effective value of the signal level (e.g., power), lengthening the duration of providing the signal, and increasing the duty cycle of the signal. The increased signal level increases heat input into the substrate W, thus increasing the temperature of the substrate W.

As shown in FIG. 7, upon the shift from step ST12 to step ST13, (II) the DC voltage applied to the ESC 1111 (ESC voltage) may be lowered to reduce the clamping force of the ESC 1111, (III) the pressure of the heat transfer gas (e.g., He gas) between the ESC 1111 and the back surface of the substrate W may be lowered, or (IV) the temperature of the heater or the temperature of the heat-transfer fluid flowing through the channel 1110a, or both may be increased. Any of these increases the temperature of the substrate W. One or more of the above temperature control processes (I) to (IV) may be performed in combination. The difference between the temperature (TL2) of the substrate W in step ST12 and the temperature (TH2) of the substrate W in step ST13 may be, for example, equal to or greater than 30° C. In one example, the temperature (TL2) of the substrate W in step ST12 may be −40 °C, and the temperature (TH2) of the substrate W in step ST13 may be 0 ° C.

The underlying film UF is exposed as etching in step ST13 proceeds. In the timing chart shown in FIG. 7, the substrate W has the higher temperature in step ST13 than in step ST12. This reduces the amount of etchant (e.g., a fluorine species in plasma) adsorbed on the underlying film UF. This reduces etching of the underlying film UF, thus improving the selectivity of the silicon-containing film SF over the underlying film UF in etching.

Upon the shift from step ST12 to step ST13, both the changing of the composition of the process gas (e.g., the changing of the composition of the process gas as described with reference to FIG. 6) and the controlling the temperature of the substrate W (e.g., the control described with reference to FIG. 7) to rise may be performed.

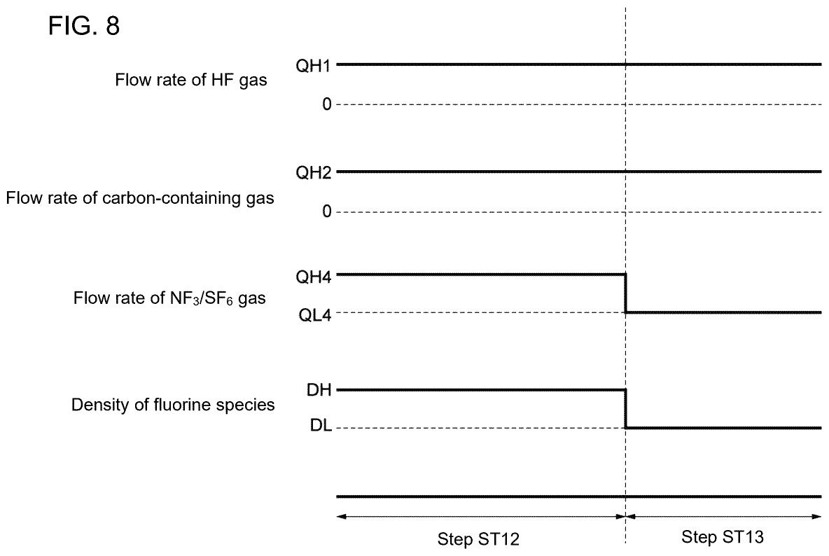

FIG. 8 is an example timing chart for an underlying film UF containing a metal. In the example in FIG. 8, step ST12 and step ST13 use process gases of different compositions. In FIG. 8, the horizontal axis indicates time. The vertical axis indicates the flow rates of the HF gas, the carbon-containing gas, and the NF3/SF6 gas included in the process gas (the first process gas or the second process gas), and the density of the fluorine species in the plasma (the first plasma or the second plasma). The flow rate QH1 and the flow rate QH2 are each higher than zero. The flow rate QL4 is lower than the flow rate QH4 or is zero. The density DL of the fluorine species in plasma is lower than the density DH of the fluorine species in plasma. In FIG. 8, the carbon-containing gas is one of a fluorocarbon gas or a hydrofluorocarbon gas, or both. For the carbon-containing gas being both a fluorocarbon gas and a hydrofluorocarbon gas, the flow rate of the carbon-containing gas is the sum of the flow rates of the fluorocarbon gas and the hydrofluorocarbon gas. In FIG. 8, the NF3/SF6 gas is an NF3 gas or an SF6 gas, or both. For the NF3/SF6 gas being both an NF3 gas and an SF6 gas, the flow rate of the NF3/SF6 gas is the sum of the flow rates of the NF3 gas and the SF6 gas. The NF3 gas and the SF6 gas are examples of the above carbon-free fluorine source that can be used in addition to an HF gas.

As shown in FIG. 8, when the underlying film UF contains a metal, the flow rate (partial pressure) of the fluorine-containing gas other than hydrogen fluoride, for example, an NF3 gas or a SF6 gas, or both, may be lowered upon the shift from step ST12 to step ST13. In addition, the flow rate of the HF gas may be lowered.

The underlying film UF is exposed as etching in step ST13 proceeds. When the underlying film UF contains a metal, the fluorine species in the plasma can react with the metal and etch the underlying film UF. In the timing chart shown in FIG. 8, the fluorine species in the second plasma generated in step ST13 has lower density than the fluorine species in the first plasma generated in step ST12. This reduces etching of the underlying film UF. In other words, this can improve the selectivity of the silicon-containing film SF over the underlying film UF in etching.

When the underlying film UF contains a metal, the temperature of the substrate W may further be controlled to rise in step ST13. The temperature of the substrate W may be controlled to rise using the one or more of the temperature control processes (I) to (IV) described above with reference to FIG. 7. This facilitates volatilization of by-products containing the metal from the underlying film UF and reduces generation of the residual including the metal. In addition to or in place of this, a gas highly reactive with the metal in the underlying film UF may be added as the second process gas. For example, a CO gas may be added as the second process gas for an underlying film UF containing tungsten. The CO gas reacts with W emitted from the underlying film UF during step ST13 to produce volatile W(CO)6. This reduces generation of the residual including the metal (W) from the underlying film UF. The second process gas may include a chlorine-containing gas such as a Cl2 gas, an SiCl4 gas, or a BCl3 gas, in addition to or in place of a CO gas.

With the etching method according to one or more embodiments, step ST13 uses processing conditions (a recipe) different from those in step ST12 to etch the silicon-containing film SF. This allows an optimum recipe to be selected appropriate for the progress of etching, or specifically, for the depth of the recess RC. For example, a recipe to increase the etching rate of the silicon-containing film SF can be selected in areas with the recess RC being shallow, and another recipe to increase the etch selectivity of the silicon-containing film SF over the underlying film UF can be selected in areas with the recess RC being deep to expose the underlying film UF.

### One or More Embodiments

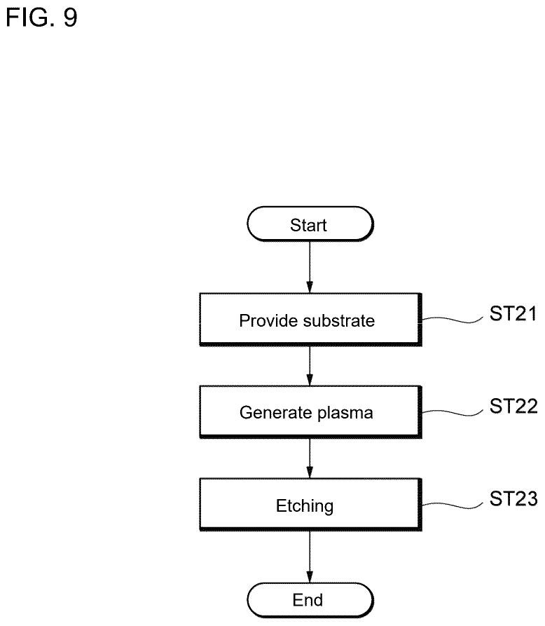

FIG. 9 is a flowchart of an etching method according to one or more embodiments. As shown in FIG. 9, the etching method according to one or more embodiments includes step ST21 of providing a substrate, step ST22 of generating plasma, and etching step ST23. The processing in each of steps ST21 to ST23 may be performed with the plasma processing system shown in FIG. 1. In other words, the etching method according to one or more embodiments may be performed using the plasma processing apparatus 1 as an etching device. The etching method according to one or more embodiments will now be described using an example in which the controller 2 controls the components of the plasma processing apparatus 1 to etch a substrate W.

### Step ST21: Providing Substrate

In step ST21, the substrate W is provided into the plasma processing space 10s of the plasma processing apparatus 1. The substrate W is provided to the central portion 111a of the substrate support 11. The substrate W is held on the substrate support 11 by the ESC 1111. The substrate W provided in step ST21 may be the same as the substrate W (refer to FIG. 3) described in one or more embodiments.

In one or more embodiments, after the substrate W is provided to the central portion 111a of the substrate support 11, the temperature of the substrate support 11 is adjusted to a set temperature by the temperature controller as in one or more embodiments. The set temperature may be, for example, 20° C. or lower, 0 ° C. or lower, −10 °C or lower, −20 °C or lower, −30 °C or lower, −40 °C or lower, −50 °C or lower, −60 °C or lower, or −70 °C or lower. The temperature of the substrate support 11 may be adjusted to the set temperature before step ST21. During the processing in steps ST22 and ST23, the temperature of the substrate support 11 may be maintained at the set temperature adjusted in step ST21.

### Step ST22: Generating Plasma

In step ST22, plasma is generated from a process gas. The gas supply 20 first supplies the process gas into the plasma processing space 10s. The process gas may be the same as the first process gas or the second process gas, or both described in one or more embodiments.

In step ST22, the source RF signal is provided to the lower electrode of the substrate support 11 or the upper electrode of the showerhead 13, or both. This generates an RF electric field between the showerhead 13 and the substrate support 11 and generates plasma from the process gas in the plasma processing space 10s.

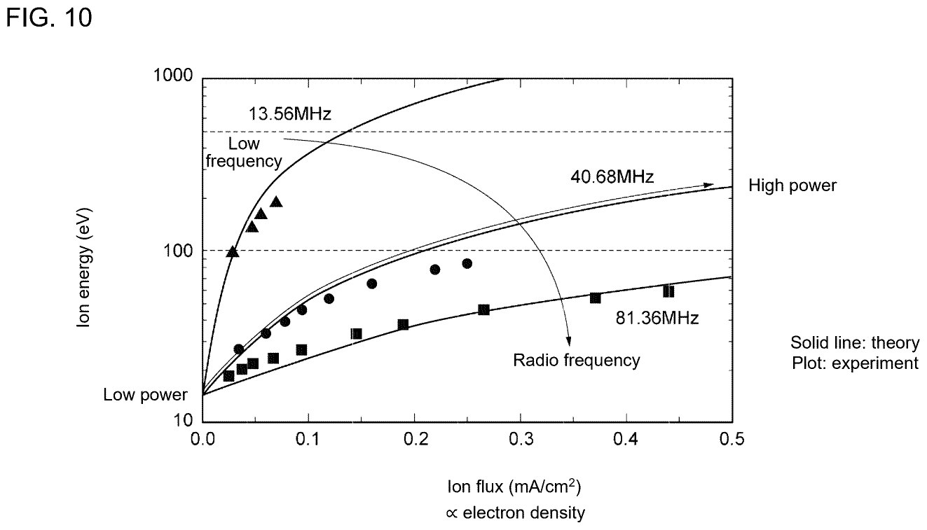

FIG. 10 is a graph showing the relationship between ion flux and ion energy. As shown in FIG. 10, the ion energy is lower for higher frequencies of the source RF signal. The ion flux is greater and the electron density is higher for higher frequencies of the source RF signal. For example, the following relationships hold for ion energy and ion flux when a source RF signal with a frequency of 40 MHz (RF 40), a source RF signal with a frequency of 60 MHz (RF 60), and a source RF signal with a frequency of 100 MHz (RF 100) are used.
Ion energy: RF40>RF60>RF100
Ion flux: RF40<RF60<RF100

In step ST22, the frequency of the source RF signal is selected to generate plasma with low ion energy and high density. Such frequency can vary based on, for example, the manner of plasma generation used by the plasma processing apparatus. For example, when the source RF signal is provided to the upper electrode and a bias signal is provided to the lower electrode in the plasma processing apparatus 1, the source RF signal may have a frequency of 40 MHz or higher. For example, when the source RF signal and the bias signal are provided to the lower electrode in the plasma processing apparatus 1, the source RF signal provided to the lower electrode of the substrate support 11 may have a frequency of 60 MHz or higher. The source RF signal may have a frequency of 150 MHz or lower or 100 MHz or lower.

In step ST22, the bias signal is provided to the lower electrode of the substrate support 11. This generates a bias potential difference between the plasma and the substrate W. The bias potential difference attracts active species such as ions and radicals in the plasma toward the substrate W. The bias signal may be the bias RF signal provided from the second RF generator 31b. The bias signal may be the bias DC signal (e.g., a sequence of voltage pulses) provided from the DC generator 32a.

In step ST22, each of the source RF signal and the bias signal may be continuous waves or pulsed waves. In step ST22, one of the source RF signal or the bias signal may be continuous waves, and the other may be pulsed waves. When both the source RF signal and the bias signal are pulsed waves, the cycles of the two pulsed waves may be synchronized. The duty cycle of the pulsed waves may be set as appropriate, and may be, for example, 1 to 80% or 5 to 50%. The duty cycle is the percentage of the period in which the level of power or voltage is higher in a pulse wave cycle. When the bias DC signal is used, the voltage pulses in the sequence may have rectangular, trapezoidal, or triangular pulse waveforms, or a combination of these. The bias DC signal may have negative or positive polarity for each voltage pulse, and may adjust the potential of the substrate W to create a potential difference between the plasma and the substrate to draw ions.

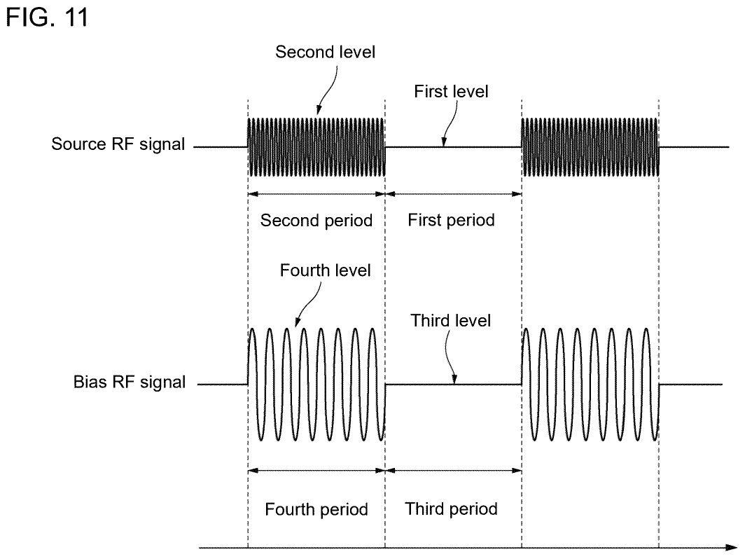

FIG. 11 is a timing chart of an example source RF signal and an example bias RF signal. In the example in FIG. 11, the source RF signal and the bias RF signal are both pulsed waves. The horizontal axis in FIG. 11 indicates time. The source RF signal has a frequency of 40 to 100 MHz inclusive in one example. The source RF signal is provided to the lower electrode of the substrate support 11 or the upper electrode of the showerhead 13, or both in a first period and a second period alternating with the first period. The source RF signal has a first level (power level) in the first period and a second level (power level) in the second period. In FIG. 11, the first level is either lower than the second level or 0 W.

The bias RF signal is provided to the lower electrode of the substrate support 11 in a third period and in a fourth period alternating with the third period. The bias RF signal has a frequency of 400 kHz to 13.56 MHz inclusive in one example. The bias RF signal has a third level (power level) in the third period and a fourth level (power level) in the fourth period. In FIG. 11, the third level is either lower than the fourth level or 0 W. As shown in FIG. 11, the second period and the fourth period may match (synchronize). The second period and the fourth period may or may not partly or entirely overlap each other.

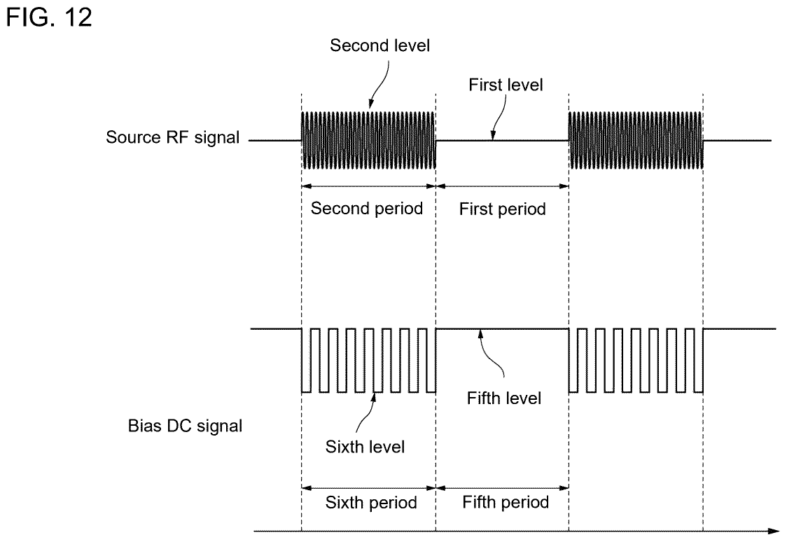

FIG. 12 is a timing chart of an example source RF signal and an example bias DC signal. In the example in FIG. 12, the source RF signal and the bias DC signal are both pulsed waves. The horizontal axis in FIG. 12 indicates time. The source RF signal in FIG. 12 is the same as the source RF signal in the example in FIG. 11. The bias DC signal is provided to the lower electrode of the substrate support 11 in a fifth period and in a sixth period alternating with the fifth period. The bias DC signal has a fifth level (voltage level) in the fifth period and a sixth level (voltage level) in the sixth period. In FIG. 12, the absolute value of the fifth level is either less than the absolute value of the sixth level or 0 V. As shown in FIG. 12, the second period and the sixth period may match (synchronize). The second period and the sixth period may or may not partly or entirely overlap each other.

In step ST22, a second bias signal may be provided to the upper electrode. The second bias signal may be the second DC signal provided from the second DC generator 32b or the bias RF signal provided from the second RF generator 31b, or both. The second bias signal may be continuous waves or pulsed waves. In this case, positive ions in the plasma processing space 10s are attracted to and collide with the upper electrode, causing emission of secondary electrons from the upper electrode. The emitted secondary electrons can modify the mask MF and improve the etching resistance of the mask MF. The emitted secondary electrons neutralize the charged substrate W, thus allowing more ions to be directed straight into the recess etched in the silicon-containing film SF. When the upper electrode is formed from a silicon-containing material, the collision of the positive ions causes emission of silicon from the upper electrode together with secondary electrons. The emitted silicon combines with oxygen in the plasma to be silicon oxide. The silicon oxide can be deposited on the mask MF to serve as a protective film. As described above, the second bias signal may be provided to the upper electrode to, for example, improve the selectivity, reduce irregular etching features, and improve the etching rate.

### Step ST23: Etching

In step ST23, the plasma generated in the plasma processing space 10s etches the silicon-containing film SF, and the recess is formed in the silicon-containing film SF based on the feature of the opening OP in the mask MF. The etching is stopped in response to the etched recess reaching a predetermined depth or the etching duration reaching a predetermined duration.

With the etching method according to one or more embodiments, the frequency of the source RF signal is set to 40 MHz or higher in step ST22. With the source RF signal having a frequency of 40 MHz or higher, the ion energy is less likely to increase in response to the power level of the source RF signal or the bias signal level (the power level of the bias RF signal or the voltage level of the bias DC signal), or both being increased to increase the electron density of the plasma. In other words, with the frequency of the source RF signal being set to 40 MHz or higher, the electron density of the generated plasma can be controlled independently of the ion energy. In step ST22, plasma with high density can thus be generated as compared with when plasma is generated with frequencies lower than 40 MHz, with less increase in the ion energy of the plasma. This increases the density of the etchant (HF species) and reduces heat input into the substrate W in the etching in step ST23. This can also facilitate adsorption of the etchant (HF species) in step ST23. Additionally, the ion energy is less likely to increase in the etching in step ST23, thus reducing damage to the mask MF. The etching method according to one or more embodiments can thus improve the etching rate of the silicon-containing film SF and also the selectivity of the silicon-containing film SF over the mask MF in etching.

### One or More Embodiments

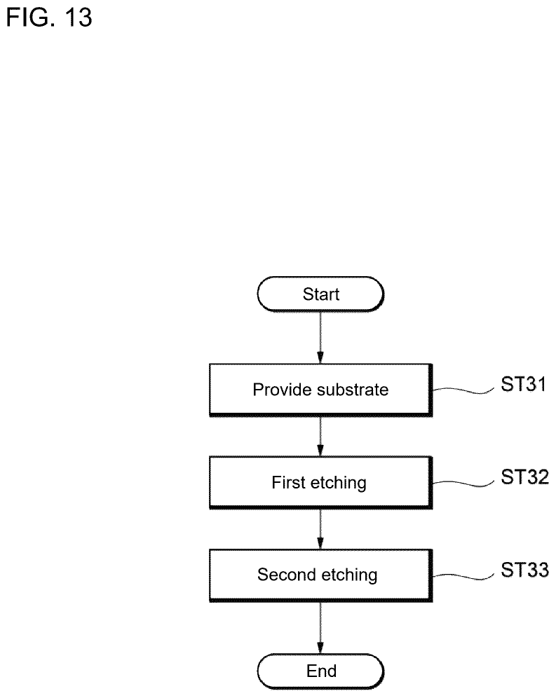

FIG. 13 is a flowchart of an etching method according to one or more embodiments. As in one or more embodiments, the etching method according to one or more embodiments includes step ST31 of providing a substrate, first etching step ST32, and second etching step ST33. The processing in each of steps ST31 to ST33 may be performed with the plasma processing system shown in FIG. 1. In other words, the etching method according to one or more embodiments may be performed using the plasma processing apparatus 1 as an etching device. The etching method according to one or more embodiments will now be described using an example in which the controller 2 controls the components of the plasma processing apparatus 1 to etch the substrate W. In one or more embodiments, the same processes and components as in the first or second embodiment will not be described or will be described briefly.

### Step ST31: Providing Substrate

In step ST31, a substrate W is provided into the plasma processing space 10s of the plasma processing apparatus 1. The substrate W is provided to the central portion 111a of the substrate support 11. The substrate W is held on the substrate support 11 by the ESC 1111. The substrate W provided in step ST31 may be the same as the substrate W (refer to FIG. 3) described in one or more embodiments.

In one or more embodiments, after the substrate W is provided to the central portion 111a of the substrate support 11, the temperature of the substrate support 11 is adjusted to a set temperature by the temperature controller. The set temperature may be, for example, 20° C. or lower, 0 ° C. or lower, −10 °C or lower, −20 °C or lower, −30 °C or lower, −40 °C or lower, −50 °C or lower, −60 °C or lower, or −70 °C or lower. In one example, adjusting or maintaining the temperature of the substrate support 11 includes causing the temperature of the heat transfer fluid flowing through the channel 1110a and the temperature of the heater to be the respective set temperatures, or to be temperatures different from the set temperatures. The heat transfer fluid may start to flow through the channel 1110a before, after, or at the same time as the substrate W is placed on the substrate support 11. The temperature of the substrate support 11 may be adjusted to the set temperature before step ST31. In other words, the substrate W may be provided to the substrate support 11 after the temperature of the substrate support 11 is adjusted to the set temperature.

### Step ST32: First Etching

In step ST32, the silicon-containing film SF is etched using plasma generated from a first process gas. The gas supply 20 first supplies the first process gas into the plasma processing space 10s. The first process gas includes an HF gas and a W-containing gas.

A source RF signal is then provided to the lower electrode of the substrate support 11 or the upper electrode of the showerhead 13, or both. This generates an RF electric field between the showerhead 13 and the substrate support 11 and generates first plasma from the first process gas in the plasma processing space 10s. A bias signal is provided to the lower electrode of the substrate support 11 to generate a bias potential difference between the plasma and the substrate W. The bias potential difference attracts active species such as ions and radicals in the plasma toward the substrate W. This etches the silicon-containing film SF, forming a recess in the silicon-containing film SF based on the feature of the opening OP in the mask MF. The first etching may be performed until before (e.g., immediately before) the underlying film UF is exposed or until the underlying film UF is at least partly exposed. More specifically, step ST32 may be ended before (or immediately before) the underlying film UF in the substrate W is exposed or when the underlying film UF is at least partly exposed.

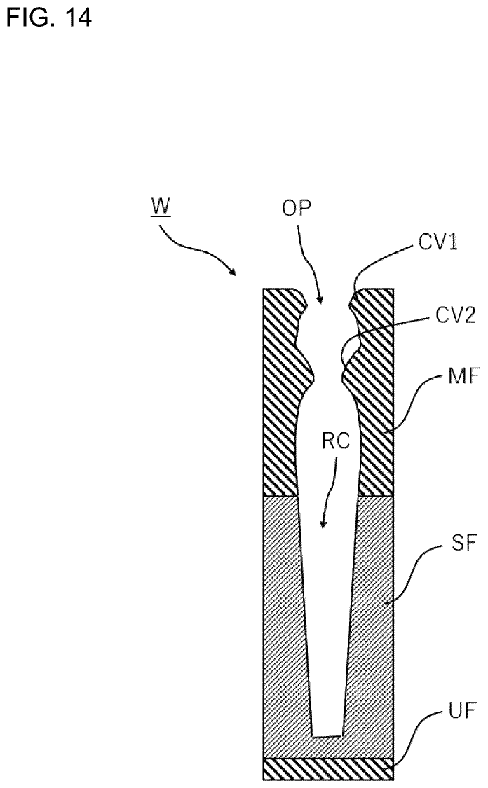

FIG. 14 is a diagram of the substrate W after step ST32 showing an example cross-sectional structure. As shown in FIG. 14, the processing in step ST32 etches a portion of the silicon-containing film SF exposed through the opening OP in the depth direction (from top to bottom in FIG. 14), forming a recess RC. In FIG. 14, the underlying film UF is not exposed after step ST32. More specifically, step ST32 may be stopped with the silicon-containing film SF partly left between the underlying film UF and the bottom of the recess RC. Step ST33 may be started in this state and may be performed for a period including the time at which the underlying film UF is exposed. In some embodiments, the underlying film UF may be at least partly exposed at the recess RC after step ST32.

In etching the silicon-containing film SF, a first protrusion CV1 forms at a first position on the side wall of the mask MF near the upper end of the opening OP. The first protrusion reduces the width of the opening OP in the mask MF. The first protrusion CV1 may be a deposit component included in the first process gas or a reaction byproduct resulting from etching, or both deposited at the first position. The first protrusion CV1 may be formed from a carbon-containing substance derived from a carbon-containing gas (described later).

As described above, the first process gas includes a W-containing gas in addition to an HF gas. This allows, in addition to the first protrusion CV1, a second protrusion CV2 to form at a second position on the side wall of the mask MF to reduce the width of the opening OP. The second position is below the first position. The second protrusion CV2 is formed from a W-containing substance (or a metal-containing substance) derived from a W-containing gas (or a metal-containing gas). The second protrusion CV2 reduces ions entering the sidewalls and the bottom of the recess RC. This structure in the present embodiment thus reduces etching of the silicon-containing film SF in the horizontal direction (bowing). The feature of the recess RC (feature in a longitudinal section) is tapered toward the bottom (or is flared).

When the first protrusion CV1 is formed from a carbon-containing substance and the second protrusion CV2 is formed from a W-containing substance (or a metal-containing substance), the amount of hydrogen chemical species and the amount of a fluorine chemical species in the first plasma may be adjusted to allow the second protrusion CV2 to form below the first protrusion CV1 in step ST32. Thus, the flow rate of a hydrogen source gas as a source of the hydrogen chemical species in the first process gas and the flow rate of a fluorine source gas as a source of the fluorine chemical species in the first process gas may be adjusted. The fluorine chemical species reduces the amount of the W-containing substance (or the metal-containing substance) near the upper end of the opening OP in the mask MF. The hydrogen chemical species reduces the amount of fluorine chemical species. Thus, the second position is lower for higher ratios of the amount of fluorine chemical species to the amount of hydrogen chemical species. Thus, the amounts of fluorine chemical species and hydrogen chemical species can be adjusted to adjust the second position at which the second protrusion CV2 forms.

In step ST32, the HF gas included in the first process gas may have the highest flow rate among the gases included in the first process gas (all the gases in the first process gas excluding an inert gas when the first process gas includes an inert gas). The flow rate of the HF gas may be adjusted to be within the same range as in one or more embodiments.

In step ST32, the tungsten-containing gas (W-containing gas) included in the first process gas may contain tungsten and a halogen. In one example, the W-containing gas is a WFxCly gas (x and y are integers from 0 to 6 inclusive, and the sum of x and y is 2 to 6inclusive). More specifically, the W-containing gas may be one or more of a gas containing tungsten and fluorine or a gas containing tungsten and chlorine. The gas containing tungsten and fluorine is, for example, a tungsten difluoride (WF2) gas, a tungsten tetrafluoride (WF4) gas, a tungsten pentafluoride (WF5) gas, or a tungsten hexafluoride (WF6) gas. The gas containing tungsten and chlorine is, for example, a tungsten dichloride (WCl2) gas, a tungsten tetrachloride (WCl4) gas, a tungsten pentachloride (WCl5) gas, or a tungsten hexachloride (WCl6) gas. Among these, the W-containing gas may be at least one of a WF6 gas or a WCl6 gas. The first process gas may include, in place of or in addition to the W-containing gas, one or more of a molybdenum-containing gas, a titanium-containing gas, or a ruthenium-containing gas. More specifically, the first process gas may include at least one metal-containing gas selected from the group consisting of a tungsten-containing gas, a molybdenum-containing gas, a titanium-containing gas, and a ruthenium-containing gas. In other words, the first process gas may include at least one metal-containing gas. The metal-containing gas may include at least one metal selected from the group consisting of tungsten, molybdenum, titanium, and ruthenium.

The first process gas may further include a phosphorus-containing gas. The first process gas may further include a carbon-containing gas. The first process gas may further include an oxygen-containing gas. The first process gas may further include a halogen-containing gas. The first process gas may include a gas containing a halogen other than fluorine, or specifically, a fluorine-free halogen-containing gas or a halogen-containing gas containing fluorine, or both. In one example, the first process gas includes a phosphorus-containing gas, a carbon-containing gas, and a halogen-containing gas, in addition to an HF gas and a W-containing gas. The phosphorus-containing gas, the carbon-containing gas, the oxygen-containing gas, and the halogen-containing gas that may be included in the first process gas may be the respective gases listed in one or more embodiments.

As described above, the first process gas may further include a halogen-containing gas, similarly to the first process gas in one or more embodiments. In one example, the halogen-containing gas may include an NF3 gas. The first process gas may include one or more other halogen-containing gases, in place of or in addition to an NF3 gas. The first process gas may further include a Cl2 gas and an HBr gas, in place of or in addition to an NF3 gas.

The first process gas may be free of any noble gas or may include a noble gas at a flow rate lower than the flow rate of the noble gas in a second process gas (described later). The first process gas may include, as the noble gas, a first noble gas or a second noble gas, or both. The first noble gas includes at least one noble gas selected from the group consisting of a krypton (Kr) gas, a xenon (Xe) gas, and a radon (Rn) gas. The second noble gas includes at least one noble gas selected from the group consisting of Ar, Ne, and He.

The first process gas may include, in place of part or all of the HF gas, a gas that can generate an HF species in the first plasma. The HF species includes at least any of a gas, radicals, or ions of HF. The gas that can generate an HF species may be a single gas or a mixed gas including fluorine and hydrogen. The single gas or the mixed gas including fluorine and hydrogen may be one of the gases listed in one or more embodiments.

### Step ST33: Second Etching

Step ST33 is performed subsequently to step ST32. In one example, step ST33 may be started before the recess RC reaches the underlying film UF. In other words, step ST33 may be started with the silicon-containing film SF partly left between the underlying film UF and the bottom of the recess RC. In some embodiments, step ST33 may be started when the underlying film UF is at least partly exposed at the recess RC. Step ST32 is shifted to step ST33 based on at least one of the depth of the recess RC, the aspect ratio of the recess RC, or an etching duration.

In step ST33, the gas supply 20 first supplies the second process gas into the plasma processing space 10s. In step ST33, a source RF signal is provided to the lower electrode of the substrate support 11 or the upper electrode of the showerhead 13, or both as in step ST12. This generates an RF electric field between the showerhead 13 and the substrate support 11 to generate second plasma from the second process gas in the plasma processing space 10s. In step ST33, a bias signal is provided to the lower electrode of the substrate support 11 to generate a bias potential difference between the plasma and the substrate W. The bias potential difference attracts active species such as ions and radicals in the plasma toward the substrate W. The active species further etches the silicon-containing film SF. Step ST33 is performed until the underlying film UF is exposed or until the underlying film UF is partly etched in the depth direction. During the processing in steps ST32 and ST33, the temperature of the substrate support 11 may be maintained at the set temperature adjusted in step ST31 or may be changed.

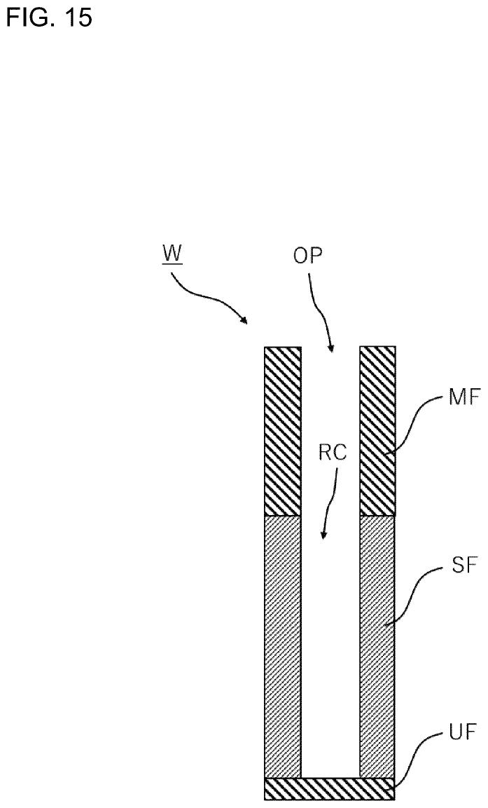

FIG. 15 is a diagram of the substrate W after step ST33 showing an example cross-sectional structure. As shown in FIG. 15, the substrate W processed in step ST33 has the bottom of the recess RC reaching the underlying film UF, with the underlying film UF being exposed at the recess RC. In this state, the underlying film UF may be partly etched in the depth direction. In step ST33, the plasma generated from the second process gas can be used to increase the opening width of the bottom of the recess RC and allow the feature of the recess RC to be rectangular (in a longitudinal section). The recess RC in this state may have an aspect ratio of, for example, 20 or more, 30 or more, 40 or more, 50 or more, or 100 or more.

In step ST33, the HF gas included in the second process gas may have the highest flow rate (partial pressure) among the gases in the second process gas (all the gases in the second process gas excluding an inert gas when the second process gas includes an inert gas). The flow rate of the HF gas may be adjusted to be within the same range as in one or more embodiments.

The second process gas may include at least one noble gas. The second process gas may include, as at least one noble gas, the first noble gas or the second noble gas, or both described above. The second process gas may include a nitrogen gas.

The second process gas may include a halogen-containing gas, similarly to the first process gas. The second process gas may include a carbon-containing gas, similarly to the first process gas.

The second process gas may be free of a W-containing gas (or a metal-containing gas) or may include a W-containing gas (or a metal-containing gas) at a flow rate lower than the flow rate of the W-containing gas in the first process gas. In one example, the second process gas is free of a W-containing gas (or a metal-containing gas). When the second process gas includes a W-containing gas (or a metal-containing gas), the W-containing gas (or the metal-containing gas) may be one of the W-containing gases (or the metal-containing gases) described above.

The second process gas may be free of a phosphorus-containing gas or may include a phosphorus-containing gas at a flow rate lower than the flow rate of the phosphorus-containing gas in the first process gas. In one example, the second process gas is free of a phosphorus-containing gas. When the second process gas includes a phosphorus-containing gas, the phosphorus-containing gas may be one of the phosphorus-containing gases described above.

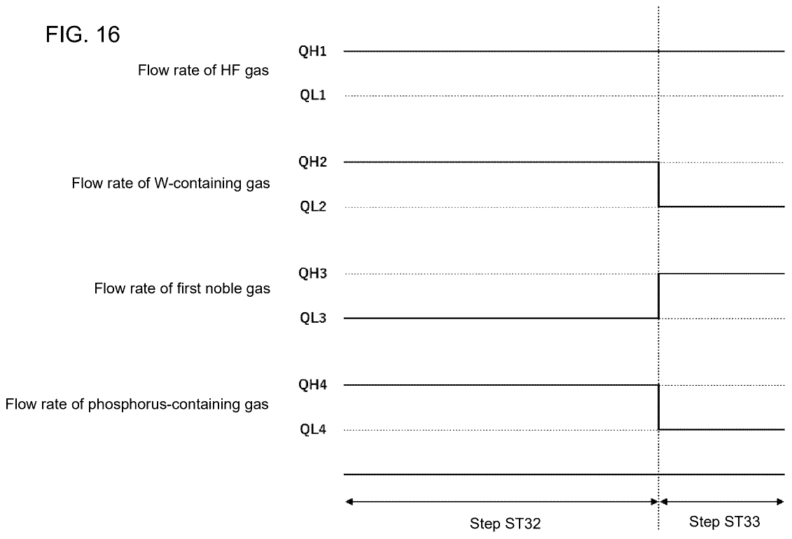

FIG. 16 is an example timing chart in one or more embodiments. In FIG. 16, the horizontal axis indicates time. The vertical axis indicates the flow rate of each of the HF gas, the W-containing gas, the first noble gas, and the phosphorus-containing gas included in the process gas (the first process gas or the second process gas). The flow rates QH1, QH2, QH3, and QH4 are each higher than zero. The flow rates QL1, QL2, QL3, and QL4 are either respectively lower than the flow rates QH1, QH2, QH3, and QH4 or zero.

As shown in FIG. 16, upon the shift from step ST32 to step ST33, the flow rate (partial pressure) of the W-containing gas (or the metal-containing gas) or the flow rate of the phosphorus-containing gas, or both may be lowered, and the flow rate (partial pressure) of the first noble gas may be increased.

With the etching method according to one or more embodiments, the silicon-containing film SF is etched with the first process gas including an HF gas and a W-containing gas (or a metal-containing gas) in step ST32. In step ST33, the silicon-containing film SF is further etched with the second process gas containing an HF gas. In step ST32, the second protrusion CV2 forming on the side wall of the mask MF reduces bowing of the silicon-containing film SF. Although the feature of the recess RC (feature in a longitudinal section) formed in step ST32 is flared, the opening width of the bottom of the recess RC can be increased in step ST33 to allow the feature of the recess RC to be rectangular. The opening width of the bottom of the recess RC in step ST33 is increased at least by the use of the second process gas with the flow rate of the W-containing gas (or the metal-containing gas) set to a less value or zero.

In the above example, step ST32 is shifted to step ST33 before the recess RC reaches the underlying film UF or when the underlying film UF is at least partly exposed. In one or more embodiments, step ST32 may be shifted to step ST33 at a time other than those described above. For example, step ST32 is shifted to step ST33 after the recess RC reaches the underlying film UF and the underlying film UF is partly etched. For example, multiple cycles each including steps ST32 and ST33 may be performed until the underlying film UF is exposed or until the underlying film UF is partly etched.

In one or more embodiments described above, the first process gas may further include a phosphorus-containing gas. The second process gas may be free of a phosphorus-containing gas or may include a phosphorus-containing gas at a flow rate lower than the flow rate of the phosphorus-containing gas in the first process gas. A phosphorus-containing gas increases the etching rate of the silicon-containing film SF at the bottom of the recess RC and reduces etching in the lateral direction on the side wall defining the recess RC. Thus, with the first process gas including a phosphorus-containing gas, the etching rate of the silicon-containing film SF can be increased, and bowing can be reduced. With the second process gas free of a phosphorus-containing gas or including a phosphorus-containing gas at a flow rate lower than the flow rate of the phosphorus-containing gas in the first process gas, the bottom width of the recess RC, or specifically, the bottom width of the recess RC near (or directly above) the underlying film UF, can be increased. As described above, step ST32 may be stopped with the silicon-containing film SF partly left between the underlying film UF and the bottom of the recess RC, and step ST33 may be started in this state.

In one or more embodiments, the second process gas may further include the above first noble gas (e.g., a xenon gas). In this case, the first process gas may be free of the first noble gas or include the first noble gas at a flow rate lower than the flow rate of the first noble gas in the second process gas. In this case, the first process gas and the second process gas may further include a halogen-containing gas. The halogen-containing gas may contain an NF3 gas. The halogen-containing gas may further include one or more other halogen-containing gases, such as a Cl2 gas or an HBr gas, or both. The second process gas including the first noble gas can be used to increase the bottom width of the recess RC, or for example, the width of the recess RC near (or directly above) the underlying film UF.

In one or more embodiments, the first process gas may further include a halogen-containing gas including an NF3 gas. The halogen-containing gas may further include, in addition to an NF3 gas, one or more other halogen-containing gases such as a Cl2 gas or an HBr gas, or both. The second process gas may also include a halogen-containing gas, similarly to the first process gas. The second process gas may be free of an NF3 gas or may include an NF3 gas at a flow rate lower than the flow rate of the NF3 gas in the first process gas. The second process gas may further include an oxygen-containing gas (e.g., an O2 gas) and a noble gas. The first process gas may be free of a noble gas or may include a noble gas at a flow rate lower than the flow rate of the noble gas in the second process gas. In this case, the noble gas in each of the first process gas and the second process gas may be the first noble gas (e.g., a xenon gas), the second noble gas (e.g., an argon gas), or both the first noble gas and the second noble gas. In this case as well, the bottom width of the recess RC, or for example, the width of the recess RC near (or directly above) the underlying film UF can be increased.

The above embodiments are mere examples described for illustrative purposes and are not intended to limit the scope of the present disclosure. The embodiments may be modified in various manners without departing from the spirit and scope of the present disclosure. For example, the etching method according to one or more embodiments may be combined with the etching method according to one or more embodiments or the etching method according to one or more embodiments, or both. The etching method according to one or more embodiments may be combined with the etching method according to one or more embodiments. For example, the etching method according to the embodiments may be performed with, other than with the plasma processing apparatus 1 using capacitively coupled plasma, a plasma processing apparatus using any plasma source for, for example, inductively coupled plasma or microwave plasma.

In the above embodiments, a metal-containing gas, such as the W-containing gas described above, is included in the process gas (e.g., the first process gas) as a metal source. However, the metal source may be an upper electrode formed from a metal-containing material or an edge ring formed from a metal-containing material, or both. In other words, the metal-containing substance emitted from the upper electrode or the edge ring, or both in the first etching process may form the second protrusion CV2.

In the etching method according to any of the above embodiments, the first process gas and the second process gas may be free of a metal-containing gas such as the W-containing gas described above. The etching method according to any of the above embodiments may use no metal source. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

In the etching method according to any of the above embodiments, the film to be etched may be other than the silicon-containing film SF.

The embodiments of the present disclosure further include the aspects described below.

### Appendix 1

An etching method implementable with a plasma processing apparatus including a chamber, the method comprising:
(a) providing a substrate into the chamber, the substrate including an underlying film and a silicon-containing film on the underlying film;
(b) etching the silicon-containing film with first plasma generated from a first process gas including a hydrogen fluoride gas to form a recess, the etching being performed until before the underlying film is exposed at the recess or until the underlying film is at least partly exposed at the recess; and
(c) further etching the silicon-containing film at the recess under a condition different from a condition in (b).

### Appendix 2

The etching method according to appendix 1, wherein
(c) includes generating second plasma using a second process gas different from the first process gas.

### Appendix 3

The etching method according to appendix 2, wherein
the second plasma has a lower fluorine species density than the first plasma.

### Appendix 4

The etching method according to appendix 2 or appendix 3, wherein
the underlying film contains silicon, and the second process gas includes a fluorocarbon gas and an oxygen-containing gas or a hydrofluorocarbon gas and an oxygen-containing gas at a flow rate of 50 vol% or greater relative to a total flow rate of the second process gas excluding a flow rate of an inert gas.

### Appendix 5

The etching method according to appendix 4, wherein
the fluorocarbon gas or the hydrofluorocarbon gas included in the second process gas has two or more carbon atoms.

### Appendix 6

The etching method according to appendix 2 or appendix 3, wherein
the underlying film contains a metal, the first process gas further includes a fluorine-containing gas other than hydrogen fluoride, and the second process gas is free of the fluorine-containing gas or includes the fluorine-containing gas at a lower partial pressure than the fluorine-containing gas in the first process gas.

### Appendix 7

The etching method according to appendix 6, wherein
the fluorine-containing gas is at least one of an NF3 gas or an SF6 gas.

### Appendix 8

The etching method according to appendix 6 or appendix 7, wherein
the second process gas further includes at least one of a CO gas or a chlorine-containing gas.

### Appendix 9

The etching method according to any one of appendixes 1 to 8, wherein
(c) includes controlling a temperature of the substrate to be higher than in (b).

### Appendix 10

The etching method according to appendix 9, wherein
the controlling the temperature includes at least one selected from the group consisting of (I) increasing power of a source radio frequency signal or power of a bias signal provided to the chamber, (II) reducing a clamping force of a substrate support supporting the substrate, (III) lowering pressure of a heat-transfer gas supplied to a space between the substrate and the substrate support, and (IV) increasing a set temperature of the substrate support to be higher than in (b).

### Appendix 11

The etching method according to appendix 9 or appendix 10, wherein
the controlling the temperature includes controlling the temperature of the substrate to be at least 30° C. higher than in (b).

### Appendix 12

The etching method according to any one of appendixes 1 to 11, wherein
(c) includes controlling pressure in the chamber to be lower than in (b).

### Appendix 13

The etching method according to appendix 12, wherein
the controlling the pressure includes controlling the pressure in the chamber to be at least 30% lower than in (b).

### Appendix 14

The etching method according to any one of appendixes 1 to 13, wherein
the first process gas further includes a phosphorus-containing gas.

### Appendix 15

The etching method according to any one of appendixes 1 to 14, wherein
the first process gas includes at least one of a carbon-containing gas or an oxygen-containing gas.

### Appendix 16

The etching method according to any one of appendixes 1 to 15, wherein
(b) includes controlling a temperature of a substrate support supporting the substrate to be 20° C. or lower.

### Appendix 17

The etching method according to any one of appendixes 1 to 16, wherein
the chamber receives a source radio frequency signal having a frequency of 40 MHz or higher.

### Appendix 18

An etching method implementable with a plasma processing apparatus including a chamber, the method comprising:
(a) providing a substrate into the chamber, the substrate including an underlying film and a silicon-containing film on the underlying film;
(b) etching the silicon-containing film with plasma including an HF species to form a recess, the etching being performed until before the underlying film is exposed at the recess or until the underlying film is at least partly exposed at the recess; and
(c) further etching the silicon-containing film at the recess under a condition different from a condition in (b).

### Appendix 19

The etching method according to appendix 18, wherein
the HF species is generated from at least one of a hydrogen fluoride gas or a hydrofluorocarbon gas.

### Appendix 20

The etching method according to appendix 18 or appendix 19, wherein
the HF species is generated from a hydrofluorocarbon gas having two or more carbon atoms.

### Appendix 21

The etching method according to appendix 18, wherein
the HF species is generated from a mixed gas including a hydrogen source and a fluorine source.

### Appendix 22

A plasma processing system, comprising:
a plasma processing apparatus including a chamber; and
controller circuitry configured to control operations including
(a) providing a substrate into the chamber, the substrate including an underlying film and a silicon-containing film on the underlying film,

(b) etching the silicon-containing film with first plasma generated from a first process gas including a hydrogen fluoride gas to form a recess, the etching being performed until before the underlying film is exposed at the recess or until the underlying film is at least partly exposed at the recess, and

(c) further etching the silicon-containing film at the recess under a condition different from a condition in (b).

### Appendix 23

A device manufacturing method implementable with a plasma processing apparatus including a chamber, the method comprising:
(a) providing a substrate into the chamber, the substrate including an underlying film and a silicon-containing film on the underlying film;
(b) etching the silicon-containing film with first plasma generated from a first process gas including a hydrogen fluoride gas to form a recess, the etching being performed until before the underlying film is exposed at the recess or until the underlying film is at least partly exposed at the recess; and
(c) further etching the silicon-containing film at the recess under a condition different from a condition in (b).

### Appendix 24

A program executable by a computer in a plasma processing system, the plasma processing system including a plasma processing apparatus and controller circuitry, the plasma processing apparatus including a chamber, the program causing the computer to control operations comprising:
(a) providing a substrate into the chamber, the substrate including an underlying film and a silicon-containing film on the underlying film;
(b) etching the silicon-containing film with first plasma generated from a first process gas including a hydrogen fluoride gas to form a recess, the etching being performed until before the underlying film is exposed at the recess or until the underlying film is at least partly exposed at the recess, and
(c) further etching the silicon-containing film at the recess under a condition different from a condition in (b).

### Appendix 25

A storage medium storing the program according to appendix 24.

### Appendix 26

An etching method implementable with a plasma processing apparatus including a chamber, the method comprising:
(a) providing a substrate into the chamber, the substrate including a silicon-containing film;
(b) supplying a process gas including a hydrogen fluoride gas into the chamber, and providing a radio frequency signal having a frequency of 40 MHz or higher to the chamber to generate plasma from the process gas; and
(c) etching the silicon-containing film with the plasma.

### Appendix 27

An etching method implementable with a plasma processing apparatus including a chamber, the method comprising:
(a) providing a substrate into the chamber, the substrate including a silicon-containing film;
(b) supplying a process gas into the chamber, and providing a radio frequency signal having a frequency of 40 MHz or higher to the chamber to generate plasma including an HF species from the process gas; and
(c) etching the silicon-containing film with the plasma.

### Appendix 28

A plasma processing system, comprising:
a plasma processing apparatus including a chamber; and
controller circuitry configured to control operations including
(a) providing a substrate into the chamber, the substrate including a silicon-containing film,
(b) supplying a process gas including a hydrogen fluoride gas into the chamber, and providing a radio frequency signal having a frequency of 40 MHz or higher to the chamber to generate plasma from the process gas, and
(c) etching the silicon-containing film with the plasma.

### Appendix 29

A device manufacturing method implementable with a plasma processing apparatus including a chamber, the method comprising:
(a) providing a substrate into the chamber, the substrate including a silicon-containing film;
(b) supplying a process gas including a hydrogen fluoride gas into the chamber, and providing a radio frequency signal having a frequency of 40 MHz or higher to the chamber to generate plasma from the process gas; and
(c) etching the silicon-containing film with the plasma.

### Appendix 30

A program executable by a computer in a plasma processing system, the plasma processing system including a plasma processing apparatus and controller circuitry, the plasma processing apparatus including a chamber, the program causing the computer to control operations comprising:
(a) providing a substrate into the chamber, the substrate including a silicon-containing film,
(b) supplying a process gas including a hydrogen fluoride gas into the chamber, and providing a radio frequency signal having a frequency of 40 MHz or higher to the chamber to generate plasma from the process gas, and
(c) etching the silicon-containing film with the plasma.

### Appendix 31

A storage medium storing the program according to appendix 30.

### Appendix A1

An etching method, comprising:
(a) providing a substrate into a chamber, the substrate including an underlying film, a silicon-containing film on the underlying film, and a mask on the silicon-containing film;
(b) etching the silicon-containing film with first plasma generated from a first process gas including a hydrogen fluoride gas and a tungsten-containing gas to form a recess; and
(c) etching, after (b), the silicon-containing film further with second plasma generated from a second process gas including a hydrogen fluoride gas, the second process gas being free of a tungsten-containing gas or including a tungsten-containing gas at a flow rate lower than a flow rate of the tungsten-containing gas in the first process gas.

### Appendix A2

The etching method according to appendix A1, wherein
the tungsten-containing gas includes WF6.

### Appendix A3

The etching method according to appendix A1 or appendix A2, wherein
the first process gas further includes a phosphorus-containing gas.

### Appendix A4

The etching method according to appendix A3, wherein
the second process gas is free of a phosphorus-containing gas or includes a phosphorus-containing gas at a flow rate lower than a flow rate of the phosphorus-containing gas in the first process gas.

### Appendix A5

The etching method according to appendix A4, wherein
etching the silicon-containing film in (b) is stopped with the silicon-containing film partly left between the underlying film and a bottom of the recess, and
etching the silicon-containing film in (c) is started with the silicon-containing film partly left between the underlying film and the bottom of the recess and is performed for a period including a time at which the underlying film is exposed.

### Appendix A6

The etching method according to any one of appendixes A1 to A5, wherein
the second process gas further includes a xenon gas.

### Appendix A7

The etching method according to appendix A6, wherein
the first process gas is free of a xenon gas or includes a xenon gas at a flow rate lower than a flow rate of the xenon gas in the second process gas.

### Appendix A8

The etching method according to appendix A7, wherein
each of the first process gas and the second process gas includes a nitrogen trifluoride gas.

### Appendix A9

The etching method according to appendix A4 or appendix A5, wherein
the first process gas includes a nitrogen trifluoride gas,
the second process gas is free of a nitrogen trifluoride gas or includes a nitrogen trifluoride gas at a flow rate lower than a flow rate of the nitrogen trifluoride gas in the first process gas,
the second process gas further includes an oxygen-containing gas and a noble gas, and
the first process gas is free of a noble gas or includes a noble gas at a flow rate lower than a flow rate of the noble gas in the second process gas.

### Appendix A10

The etching method according to any one of appendixes A1 to A9, wherein
(b) is performed until before the underlying film is exposed at the recess or until the underlying film is at least partly exposed at the recess.

### Appendix A11

The etching method according to any one of appendixes A1 to A9, wherein
(b) is performed until the underlying film is partly etched.

### Appendix A12

The etching method according to any one of appendixes A1 to A9, wherein
a plurality of cycles each including (b) and (c) are performed.

### Appendix A13

The etching method according to any one of appendixes A1 to A12, wherein
while the silicon-containing film is being etched in (b), a first protrusion and a second protrusion form on the mask, the first protrusion is at a first position and reduces a width of an opening in the mask, and the second protrusion is at a second position below the first position and reduces the width of the opening in the mask.

### Appendix A14

The etching method according to appendix A13, wherein
the first process gas further includes a carbon-containing gas being a source of the first protrusion,
the tungsten-containing gas in the first process gas is a source of the second protrusion, and
(b) includes adjusting an amount of a hydrogen chemical species and an amount of a fluorine chemical species in the first plasma to allow the second protrusion to form below the first protrusion.

### Appendix A15

The etching method according to any one of appendixes A1 to A14, wherein
(b) includes forming a flared recess in the silicon-containing film, and
(c) includes etching the silicon-containing film to change a feature of the flared recess to a rectangle.

### Appendix A16

An etching method, comprising:
(a) providing a substrate into a chamber, the substrate including an underlying film, a silicon-containing film on the underlying film, and a mask on the silicon-containing film;
(b) etching the silicon-containing film with first plasma generated from a first process gas to form a recess; and
(c) etching, after (b), the silicon-containing film further with second plasma generated from a second process gas,
wherein the first process gas includes a single gas or a mixed gas including fluorine and hydrogen, and a metal-containing gas,
the second process gas includes a single gas or a mixed gas including fluorine and hydrogen, and
the second process gas is free of the metal-containing gas or includes the metal-containing gas at a flow rate lower than a flow rate of the metal-containing gas in the first process gas.

### Appendix A17

The etching method according to appendix A16, wherein
the metal-containing gas includes at least one metal selected from the group consisting of tungsten, molybdenum, titanium, and ruthenium.

### Appendix A18

The etching method according to appendix A16 or appendix A17, wherein
the first process gas further includes a phosphorus-containing gas.

### Appendix A19

The etching method according to appendix A18, wherein
the second process gas is free of a phosphorus-containing gas or includes a phosphorus-containing gas at a flow rate lower than a flow rate of the phosphorus-containing gas in the first process gas.

### Appendix A20

The etching method according to appendix A19, wherein
etching the silicon-containing film in (b) is stopped with the silicon-containing film partly left between the underlying film and a bottom of the recess, and
etching the silicon-containing film in (c) is started with the silicon-containing film partly left between the underlying film and the bottom of the recess and is performed for a period including a time at which the underlying film is exposed.

### Appendix A21

The etching method according to any one of appendixes A16 to A20, wherein
the second process gas further includes a noble gas.

### Appendix A22

The etching method according to appendix A21, wherein
the first process gas is free of the noble gas or includes the noble gas at a flow rate lower than a flow rate of the noble gas in the second process gas.

### Appendix A23

The etching method according to appendix A21 or appendix A22, wherein
the noble gas includes at least one selected from the group consisting of an argon gas, a krypton gas, a xenon gas, and a radon gas.

### Appendix A24

The etching method according to appendix A22 or appendix A23, wherein
each of the first process gas and the second process gas includes a nitrogen trifluoride gas.

### Appendix A25

The etching method according to appendix A19 or appendix A20, wherein
the first process gas includes a nitrogen trifluoride gas,
the second process gas is free of a nitrogen trifluoride gas or includes a nitrogen trifluoride gas at a flow rate lower than a flow rate of the nitrogen trifluoride gas in the first process gas,
the second process gas further includes an oxygen-containing gas and a noble gas, and
the first process gas is free of a noble gas or includes a noble gas at a flow rate lower than a flow rate of the noble gas in the second process gas.

### Appendix A26

The etching method according to any one of appendixes A16 to A25, wherein
while the silicon-containing film is being etched in (b), a first protrusion and a second protrusion form on the mask, the first protrusion is at a first position and reduces a width of an opening in the mask, and the second protrusion is at a second position below the first position and reduces the width of the opening in the mask.

### Appendix A27

The etching method according to appendix A26, wherein
the first process gas further includes a carbon-containing gas being a source of the first protrusion,
the metal-containing gas in the first process gas is a source of the second protrusion, and
(b) includes adjusting an amount of a hydrogen chemical species and an amount of a fluorine chemical species in the first plasma to allow the second protrusion to form below the first protrusion.

### Appendix A28

An etching device, comprising:
a chamber;

A Substrate Support in the Chamber;
a plasma generator; and
controller circuitry configured to control the plasma generator to perform processes including
(a) providing a substrate into the chamber, the substrate including an underlying film, a silicon-containing film on the underlying film, and a mask on the silicon-containing film,
(b) etching the silicon-containing film with first plasma generated from a first process gas including a hydrogen fluoride gas and a tungsten-containing gas to form a recess, and
(c) etching, after (b), the silicon-containing film further with second plasma generated from a second process gas including a hydrogen fluoride gas, the second process gas being free of the tungsten-containing gas or including the tungsten-containing gas at a flow rate lower than a flow rate of the tungsten-containing gas in the first process gas.

### Appendix A29

The etching device according to appendix A28, wherein
the tungsten-containing gas includes WF6.

### Appendix A30

The etching device according to appendix A28 or appendix A29, wherein
the first process gas further includes a phosphorus-containing gas.

### Appendix A31

The etching device according to appendix A30, wherein
the second process gas is free of a phosphorus-containing gas or includes a phosphorus-containing gas at a flow rate lower than a flow rate of the phosphorus-containing gas in the first process gas.

### Appendix A32

The etching device according to appendix A31, wherein
the controller circuitry stops etching of the silicon-containing film in (b) with the silicon-containing film partly left between the underlying film and a bottom of the recess, and
the controller circuitry starts etching of the silicon-containing film in (c) with the silicon-containing film partly left between the underlying film and the bottom of the recess and causes the etching to be performed for a period including a time at which the underlying film is exposed.

### Appendix A33

The etching device according to any one of appendixes A28 to A32, wherein
the second process gas further includes a xenon gas.

### Appendix A34

The etching device according to appendix A33, wherein
the first process gas is free of a xenon gas or includes a xenon gas at a flow rate lower than a flow rate of the xenon gas in the second process gas.

### Appendix A35

The etching device according to appendix A34, wherein
each of the first process gas and the second process gas includes a nitrogen trifluoride gas.

### Appendix A36

The etching device according to appendix A31 or appendix A32, wherein
the first process gas includes a nitrogen trifluoride gas,
the second process gas is free of a nitrogen trifluoride gas or includes a nitrogen trifluoride gas at a flow rate lower than a flow rate of the nitrogen trifluoride gas in the first process gas,
the second process gas further includes an oxygen-containing gas and a noble gas, and
the first process gas is free of a noble gas or includes a noble gas at a flow rate lower than a flow rate of the noble gas in the second process gas.

### Appendix A37

The etching device according to any one of appendixes A28 to A36, wherein
the first process gas further includes a carbon-containing gas being a source for forming a first protrusion at a first position on the mask and reduces a width of an opening of the mask,
the tungsten-containing gas in the first process gas is a source for forming a second protrusion at a second position on the mask below the first position and reduces the width of the opening of the mask, and
the controller circuitry adjusts an amount of a hydrogen chemical species and an amount of a fluorine chemical species in the first plasma to allow the second protrusion to form below the first protrusion in (b).

### Appendix A38

The etching device according to any one of appendixes A28 to A37, further comprising:
a gas supply configured to supply the first process gas and the second process gas into the chamber,
wherein the controller circuitry further controls the gas supply.

### Appendix A39

An etching device, comprising:
a chamber;
a substrate support in the chamber;
a plasma generator; and
controller circuitry configured to control the plasma generator to perform processes including
(a) providing a substrate into the chamber, the substrate including an etching target film and a mask on the etching target film, and
(b) etching the etching target film with plasma generated from a process gas including a hydrogen fluoride gas to form a recess,
the controller circuitry being configured to cause (b) to be performed with a metal source in the chamber to allow a first protrusion and a second protrusion to form on the mask while the etching target film is being etched, the first protrusion being at a first position and reduces a width of an opening in the mask, the second protrusion being at a second position below the first position and reduces the width of the opening in the mask.

### Appendix A40

The etching device according to appendix A39, wherein
the process gas further includes a metal-containing gas, and
the metal source is the metal-containing gas.

### Appendix A41

The etching device according to appendix A39, wherein
the metal source is at least one of an upper electrode comprising a metal-containing material or an edge ring comprising a metal-containing material, the upper electrode is located above the substrate support and facing the substrate support, and the edge ring surrounds the substrate supported on the substrate support.

Some working examples will now be described.

### First and Second Working Examples

In the first and second working examples, silicon-containing films in sample substrates were etched with the plasma processing apparatus 1. Each sample substrate included a multilayer film as a silicon-containing film on an underlying film and a mask formed from amorphous carbon on the multilayer film. The multilayer film included multiple silicon oxide films and multiple silicon nitride films alternately stacked on one another. The etching in the first and second working examples included first etching and second etching following the first etching. In the first working example, a first process gas used in the first etching was a mixed gas including an HF gas, a PF3 gas, and a halogen-containing gas. The halogen-containing gas included an NF3 gas, a Cl2 gas, and an HBr gas. In the first working example, a second process gas used in the second etching was the same mixed gas as the first process gas except that the mixed gas was free of a PF3 gas. In the second working example, the same mixed gas as the first process gas in the first working example was used as a first process gas in the first etching and as a second process gas in the second etching. In the first and second working examples, the first etching was stopped with the silicon-containing film partly left between the underlying film and the bottom of the recess, and the second etching was started in this state.

In the first and second working examples, the maximum width of the recess (specifically, bowing CD) formed in the silicon-containing film and the bottom width of the recess (specifically, bottom CD) were determined. The difference between the bowing CD and the bottom CD, or specifically, a CD bias, was then determined. The bowing CD in the first working example was substantially the same as the bowing CD in the second working example. The bottom CD in the first working example was about 11 nm larger than the bottom CD in the second working example. The CD bias in the second working example was 47.6 nm whereas the CD bias in the first working example was 35.2 nm. The results reveal that the bottom CD can be extended to reduce the CD bias, or specifically, the feature of the recess in a longitudinal section can be rectangular, by reducing the flow rate of the phosphorus-containing gas in the second process gas to be lower than the flow rate of the phosphorus-containing gas in the first process gas or by setting the flow rate of the phosphorus-containing gas in the second process gas to zero.

### Third to Fifth Working Examples

In the third to fifth working examples, silicon-containing films in the same sample substrates as in the first working example were etched using the plasma processing apparatus 1. The etching in the third to fifth working examples included first etching and second etching following the first etching. In the third and fourth working examples, a first process gas used in the first etching was a mixed gas including an HF gas, a WF6 gas, a PF3 gas, a halogen-containing gas, and a carbon-containing gas. The halogen-containing gas included an NF3 gas, a Cl2 gas, and an HBr gas. The carbon-containing gas included a hydrofluorocarbon gas. In the third working example, a second process gas used in the second etching was the same mixed gas as the first process gas in the third example except that the mixed gas was free of a WF6 gas and a PF3 gas. In the fourth working example, a second process gas used in the second etching was the same mixed gas as the first process gas in the fourth working example except that the mixed gas was free of a WF6 gas and a PF3 gas but further included a xenon gas. In the fifth working example, a first process gas used in the first etching was the same mixed gas as the first process gas in the third working example except that the mixed gas is free of a WF6 gas. In the fifth working example, the second process gas used in the second etching was the same mixed gas as the second process gas in the third working example. In the third to fifth working examples, the first etching was stopped with the silicon-containing film partly left between the underlying film and the bottom of the recess, and the second etching was started in this state.

In the third to fifth working examples, the maximum width of the recess (specifically, bowing CD) formed in the silicon-containing film and the bottom width of the recess (specifically, bottom CD) were determined. The difference between the bowing CD and the bottom CD, or specifically, a CD bias, was then determined. The bowing CD in each of the third and fourth working examples was about 7 nm smaller than the bowing CD in the fifth working example. The results reveal that the use of the first process gas including a metal-containing gas such as a WF6 gas can reduce bowing. The bottom CD in the third working example was substantially the same as the bottom CD in the fifth working example, but the bottom CD in the fourth working example was about 5 nm larger than the bottom CD in the fifth working example. This reveals that the use of the second process gas including a first noble gas such as a xenon gas can yield a relatively large bottom CD. The CD bias in the fifth working example was 37.6 nm, whereas the bottom CD in the third working example was 33.7 nm and the bottom CD in the fourth working example was 25.9 nm. The results reveal that the use of the first process gas including a metal-containing gas such as a WF6 gas can reduce bowing CD and allow the feature of the recess in a longitudinal section to be rectangular. The results also reveal that the use of the second process gas including a first noble gas such as a xenon gas can extend the bottom CD to further allow the feature of the recess in a longitudinal section to be rectangular.

### Sixth and Seventh Working Examples

In the sixth and seventh working examples, silicon-containing films in the same sample substrates as in the first working example were etched using the plasma processing apparatus 1. The etching in the sixth and seventh examples included first etching and second etching following the first etching. In the sixth and seventh working examples, a first process gas used in the first etching was a mixed gas including an HF gas, a PF3 gas, a halogen-containing gas, and a carbon-containing gas. The halogen-containing gas included an NF3 gas, a Cl2 gas, and an HBr gas. The carbon-containing gas included a fluorocarbon gas. In the sixth and seventh working examples, a second process gas used in the second etching was a mixed gas including a noble gas, in addition to all the gases in the first process gas in each working example. In the sixth working example, the noble gas was a xenon gas. In the seventh working example, the noble gas was an argon gas. In the sixth and seventh working examples, the first etching was stopped with the silicon-containing film partly left between the underlying film and the bottom of the recess, and the second etching was started in this state.

In the sixth and seventh working examples, the maximum width of the recess (specifically, bowing CD) in the silicon-containing film and the bottom width of the recess (specifically, bottom CD) were determined. The difference between the bowing CD and the bottom CD, or specifically, a CD bias, was then determined. The bowing CDs in the sixth and seventh working examples were substantially the same. The bottom CD in the sixth working example was 29 nm larger than the bottom CD in the seventh working example. The CD bias in the seventh working example was 67 nm, whereas the CD bias in the sixth working example was 30 nm. The results reveal that the use of the first noble gas such as a xenon gas in the second etching can extend the bottom CD to further allow the feature of the recess in a longitudinal section to be rectangular.

### Eighth to Tenth Working Examples

In the eighth to tenth working examples, silicon-containing films in the same sample substrates as in the first working example were etched using the plasma processing apparatus 1. The etching in the eighth to tenth working examples included first etching and second etching following the first etching. In the eighth to tenth working examples, a first process gas used in the first etching was a mixed gas including an HF gas, a WF6 gas, a PF3 gas, a halogen-containing gas, and a carbon-containing gas. The halogen-containing gas included an NF3 gas, a Cl2 gas, and an HBr gas. The carbon-containing gas included a hydrofluorocarbon gas. In the eighth working example, a second process gas used in the second etching was the same mixed gas as the first process gas in the eighth working example except that the mixed gas was free of a WF6 gas and a PF3 gas but further included a xenon gas. In the ninth working example, a second process gas used in the second etching was the same mixed gas as the second process gas in the eighth working example except that the mixed gas included an O2 gas in place of an NF3 gas. In the tenth working example, a second process gas used in the second etching was the same mixed gas as the second process gas in the ninth working example except that the mixed gas included an argon gas in place of a xenon gas.

In the eighth to tenth working examples, the maximum width of the recess (specifically, bowing CD) in the silicon-containing film and the bottom width of the recess (specifically, bottom CD) were determined. The difference between the bowing CD and the bottom CD, or specifically, a CD bias, was then determined. In the ninth working example, the bottom CD was 0.7 nm smaller than the bottom CD in the eighth working example, whereas the bowing CD was 2.3 nm smaller than the bowing CD in the eighth working example. Thus, the CD bias in the ninth working example was 1.6 nm smaller than the CD bias in the eighth working example. The results reveal that the use of an oxygen-containing gas such as an O2 gas in place of an NF3 gas in the second etching reduces bowing to further allow the feature of the recess in a longitudinal section to be rectangular. In the tenth working example, the bottom CD was extended to be larger than in the ninth working example, and thus the CD bias was 2.3 nm smaller than the CD bias in the ninth working example. The results reveal that the use of the second noble gas such as an argon gas together with an O2 gas replacing an NF3 gas in the second etching extends the bottom CD to further allow the feature of the recess in a longitudinal section to be rectangular.

Various exemplary embodiments according to the present disclosure have been described by way of example, and various changes may be made without departing from the scope and spirit of the present disclosure. The embodiments described herein are thus not restrictive, and the true scope and spirit of the present disclosure are defined by the appended claims.

### REFERENCE SIGNS LIST

1 Plasma processing apparatus
2 Controller
10 Plasma processing chamber
10s Plasma processing space
11 Substrate support
13 Showerhead
20 Gas supply
31a First RF generator
31b Second RF generator
32a First DC generator
SF Silicon-containing film
MF Mask
OP Opening
RC Recess
UF Underlying film
W Substrate

1. An etching method, comprising:
(a) providing a substrate into a chamber, the substrate including an underlying film, a silicon-containing film on the underlying film, and a mask on the silicon-containing film;
(b) etching the silicon-containing film with first plasma generated from a first process gas including a hydrogen fluoride gas and a tungsten-containing gas to form a recess; and
(c) etching, after (b), the silicon-containing film further with second plasma generated from a second process gas including a hydrogen fluoride gas, the second process gas being free of a tungsten-containing gas or including a tungsten-containing gas at a flow rate lower than a flow rate of the tungsten-containing gas in the first process gas.

2. The etching method according to claim 1, wherein
the tungsten-containing gas includes WF₆.

3. The etching method according to claim 1, wherein
the first process gas further includes a phosphorus-containing gas, and
the second process gas is free of a phosphorus-containing gas or includes a phosphorus-containing gas at a flow rate lower than a flow rate of the phosphorus-containing gas in the first process gas.

4. The etching method according to claim 1, wherein
the second process gas further includes a xenon gas.

5. The etching method according to claim 4, wherein
the first process gas is free of a xenon gas or includes a xenon gas at a flow rate lower than a flow rate of the xenon gas in the second process gas.

6. The etching method according to claim 5, wherein
each of the first process gas and the second process gas includes a nitrogen trifluoride gas.

7. The etching method according to claim 3, wherein
the first process gas further includes a nitrogen trifluoride gas,
the second process gas is free of a nitrogen trifluoride gas or includes a nitrogen trifluoride gas at a flow rate lower than a flow rate of the nitrogen trifluoride gas in the first process gas,
the second process gas further includes an oxygen-containing gas and a noble gas, and
the first process gas is free of a noble gas or includes a noble gas at a flow rate lower than a flow rate of the noble gas in the second process gas.

8. The etching method according to claim 1, wherein
(b) is performed until before the underlying film is exposed at the recess or until the underlying film is at least partly exposed at the recess.

9. The etching method according to claim 1, wherein
(b) is performed until the underlying film is partly etched.

10. The etching method according to claim 1, wherein
a plurality of cycles each including (b) and (c) are performed.

11. The etching method according to claim 1, wherein
while the silicon-containing film is being etched in (b), a first protrusion and a second protrusion form on the mask,
the first protrusion is at a first position and reduces a width of an opening in the mask, and
the second protrusion is at a second position below the first position and reduces the width of the opening in the mask.

12. The etching method according to claim 11, wherein
the first process gas further includes a carbon-containing gas being a source of the first protrusion,
the tungsten-containing gas in the first process gas is a source of the second protrusion, and
(b) includes adjusting an amount of a hydrogen chemical species and an amount of a fluorine chemical species in the first plasma to allow the second protrusion to form below the first protrusion.

13. The etching method according to claim 1, wherein
(b) includes forming a flared recess in the silicon-containing film, and
(c) includes etching the silicon-containing film to change a portion of the flared recess to a rectangular shape.

14. An etching method, comprising:
(a) providing a substrate into a chamber, the substrate including an underlying film, a silicon-containing film on the underlying film, and a mask on the silicon-containing film;
(b) etching the silicon-containing film with first plasma generated from a first process gas to form a recess; and
(c) etching, after (b), the silicon-containing film further with second plasma generated from a second process gas,
wherein the first process gas includes a single gas or a mixed gas including fluorine and hydrogen, and a metal-containing gas,
the second process gas includes a single gas or a mixed gas including fluorine and hydrogen, and
the second process gas is free of the metal-containing gas or includes the metal-containing gas at a flow rate lower than a flow rate of the metal-containing gas in the first process gas.

15. The etching method according to claim 14, wherein
the metal-containing gas includes at least one metal selected from the group consisting of tungsten, molybdenum, titanium, and ruthenium.

16. The etching method according to claim 14, wherein
the first process gas further includes a phosphorus-containing gas, and
the second process gas is free of a phosphorus-containing gas or includes a phosphorus-containing gas at a flow rate lower than a flow rate of the phosphorus-containing gas in the first process gas.

17. The etching method according to claim 14, wherein the second process gas further includes a noble gas.

18. The etching method according to claim 17, wherein
the first process gas is free of the noble gas or includes the noble gas at a flow rate lower than a flow rate of the noble gas in the second process gas.

19. The etching method according to claim 17, wherein
the noble gas includes at least one selected from the group consisting of an argon gas, a krypton gas, a xenon gas, and a radon gas.

20. An etching device, comprising:
a chamber;
a substrate support in the chamber;
a plasma generator; and
controller circuitry configured to control the plasma generator to perform processes including:
(a) providing a substrate into the chamber, the substrate including an underlying film, a silicon-containing film on the underlying film, and a mask on the silicon-containing film,
(b) etching the silicon-containing film with first plasma generated from a first process gas including a hydrogen fluoride gas and a tungsten-containing gas to form a recess, and
(c) etching, after (b), the silicon-containing film further with second plasma generated from a second process gas including a hydrogen fluoride gas, the second process gas being free of the tungsten-containing gas or including the tungsten-containing gas at a flow rate lower than a flow rate of the tungsten-containing gas in the first process gas.
